(19) United States
(12) Patent Application Publication
(10) Pub. No.: US 2025/0031369 A1
(43) Pub. Date: Jan. 23, 2025

(54) SEMICONDUCTOR MEMORY DEVICE

(71) Applicant: SK hynix Inc., Icheon-si Gyeonggi-do (KR)

(72) Inventor: Nam Jae LEE, Icheon-si Gyeonggi-do (KR)

(73) Assignee: SK hynix Inc., Icheon-si Gyeonggi-do (KR)

(21) Appl. No.: 18/392,536

(22) Filed: Dec. 21, 2023

(30) Foreign Application Priority Data
Jul. 20, 2023 (KR) 10-2023-0094708

(51) Int. Cl. H10B 43/27; H01L 23/00; H01L 25/00; H01L 25/065; H01L 25/18; H10B 41/27; H10B 80/00

(52) U.S. Cl. CPC H10B 43/27; H01L 24/08; H01L 24/80; H01L 25/0657; H01L 25/18; H01L 25/50; H10B 41/27; H10B 80/00; H01L 2224/08135; H01L 2224/80895; H01L 2224/80896; H01L 2924/1431; H01L 2924/14511

(57) ABSTRACT

There are provided a semiconductor memory device and a method of manufacturing the semiconductor memory device. The semiconductor memory device includes a pass gate, a plurality of active pillars respectively disposed in a plurality of active holes included in the pass gate, and a gate stack, the pass gate disposed over the gate stack in a first direction.

### CROSS-REFERENCE TO RELATED APPLICATION

The present application claims priority under 35 U.S.C. § 119 (a) to Korean patent application number 10-2023-0094708 filed on Jul. 20, 2023, in the Korean Intellectual Property Office, the entire disclosure of which is incorporated by reference herein.

### BACKGROUND

### 1. Technical Field

The present disclosure relates to a semiconductor memory device and a method of manufacturing the semiconductor memory device, and more particularly, to a three-dimensional semiconductor memory device and a method of manufacturing the three-dimensional semiconductor memory device.

### 2. Related Art

A semiconductor memory device is applied to electronic devices of various fields, such as an automobile, a medical care, and a data center, as well as a small electronic device. Accordingly, demand for the semiconductor memory device is increasing.

The semiconductor memory device may include a memory cell for data storage. In order to increase a capacity of the semiconductor memory device, technology development for a three-dimensional semiconductor memory device including memory cells arranged in a three-dimension is being actively progressed.

### SUMMARY

According to an embodiment of the present disclosure, a semiconductor memory device may include a pass gate, a plurality of active pillars respectively disposed in a plurality of active holes included in the pass gate, and a gate stack, the pass gate disposed over the gate stack in a first direction, and the gate stack may include a plurality of conductive patterns spaced apart from each other in the first direction and stacked in the first direction.

According to an embodiment of the present disclosure, a semiconductor memory device may include a peripheral circuit structure including a first region and a second region, a pass gate spaced apart from the peripheral circuit structure in a first direction and overlapping the first region of the peripheral circuit structure, an active pillar disposed in an active hole of the pass gate, a doped semiconductor layer spaced apart from the peripheral circuit structure in the first direction and overlapping the second region of the peripheral circuit structure, a gate stack including a contact region between the first region of the peripheral circuit structure and the pass gate, and a cell array region extending from the contact region to overlap the second region of the peripheral circuit structure, a channel pillar connected to the doped semiconductor layer and passing through the cell array region of the gate stack, a memory layer between the channel pillar and the gate stack, and a gate contact plug connected to the active pillar and passing through the contact region of the gate stack.

According to an embodiment of the present disclosure, a method of manufacturing a semiconductor memory device may include forming a plurality of active pillars by etching a first region in a semiconductor substrate including the first region and a second region, forming an insulating layer surrounding a side of each of the plurality of active pillars, forming a pass gate surrounding the plurality of active pillars with the insulating film interposed therebetween, forming a memory cell array, the memory cell array including a gate stack overlapping the plurality of active pillars and the second region of the semiconductor substrate, a channel hole extending into the second region of the semiconductor substrate by passing through the gate stack, and a memory layer and a channel pillar disposed inside the channel hole, forming a first conductive bonding pattern over the memory cell array, forming a structure including a peripheral circuit structure and a second conductive bonding pattern, performing a bonding process to connect the first conductive bonding pattern and the second conductive bonding pattern, and separating the plurality of active pillars from each other by removing a portion of the semiconductor substrate.

### BRIEF DESCRIPTION OF THE DRAWINGS

FIG. 1 is a block diagram illustrating a semiconductor memory device according to an embodiment of the present disclosure.

FIG. 2 is a circuit diagram illustrating a memory cell array and a pass circuit according to an embodiment of the present disclosure.

FIGS. 3, 4, 5, 6, 7A, and 7B are diagrams illustrating a semiconductor memory device according to an embodiment of the present disclosure.

FIGS. 8A, 8B, 8C, 9A, 9B, 10A, 10B, 10C, 11A, 11B, 11C, 11D, 12A, 12B, 13A, 13B, 13C, 13D, 13E, 13F, 13G, 13H, 13I, and 13J are diagrams illustrating a method of manufacturing a semiconductor memory device according to an embodiment of the present disclosure.

FIG. 14 is a block diagram illustrating an electronic system including a semiconductor memory device according to an embodiment of the present disclosure.

### DETAILED DESCRIPTION

The specific structural and functional descriptions disclosed herein are merely illustrative for the purpose of describing embodiments according to the concept of the present disclosure. The embodiments according to the concept of the present disclosure can be modified in various forms and replaced with other equivalent embodiments. Thus the present disclosure should not be construed as limited to the embodiments set forth herein.

It will be understood that, although the terms “first,” “second,” etc. may be used herein to describe various elements, these elements should not be limited by these terms. These terms are used to distinguish one element from another element, and the order or number of components is not limited by the terms. In addition, it is not construed as limiting the number of components unless there is a special limitation on components expressed in singular or plural numbers.

Embodiments of the present disclosure may provide a semiconductor memory device and a method of manufacturing the same capable of improving an integration degree.

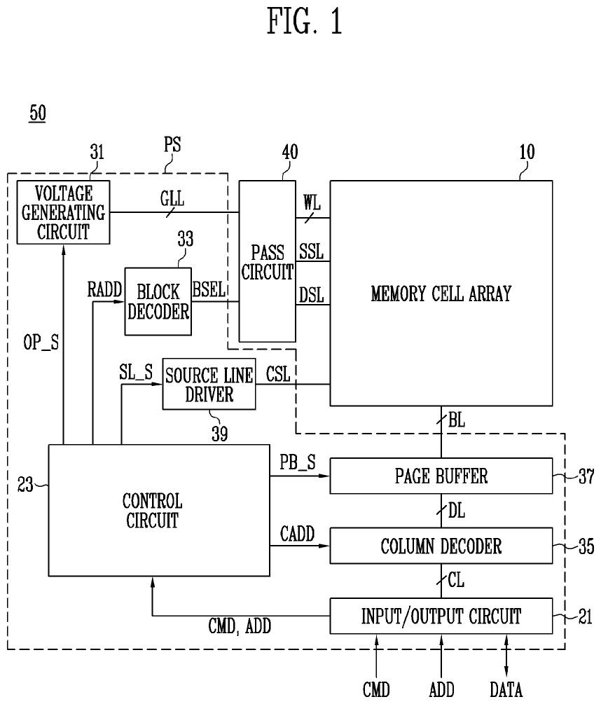

FIG. 1 is a block diagram illustrating a semiconductor memory device according to an embodiment of the present disclosure.

Referring to FIG. 1, the semiconductor memory device 50 may include a memory cell array 10, a pass circuit 40, and a peripheral circuit structure PS.

The memory cell array 10 may include a plurality of memory blocks. Each of the memory blocks may include a plurality of memory cells. Each of the memory cells may be a nonvolatile memory cell. As an embodiment, each memory cell may be a NAND flash memory cell. Hereinafter, an embodiment of the present disclosure is described based on the semiconductor memory device 50 including the NAND flash memory cell, but the present disclosure is not limited thereto. As another embodiment, each memory cell may be configured of a ferroelectric memory cell, a variable resistance memory cell, or the like.

The pass circuit 40 may be connected to the memory cell array 10 through a plurality of local lines. As an embodiment, the plurality of local lines may include a plurality of word lines WL, at least one source select line SSL, and at least one drain select line DSL.

The peripheral circuit structure PS may be configured to perform a program operation for storing data in the memory cell array 10, a read operation for outputting data stored in the memory cell array 10, and an erase operation for erasing data stored in the memory cell array 10. As an embodiment, the peripheral circuit structure PS may include an input/output circuit 21, a control circuit 23, a voltage generating circuit 31, a block decoder 33, a column decoder 35, a page buffer 37, and a source line driver 39.

The input/output circuit 21 may transfer a command CMD and an address ADD received from an external device (for example, a memory controller) of the semiconductor memory device 50 to the control circuit 23. The input/output circuit 21 may exchange data DATA with the external device and the column decoder 35.

The control circuit 23 may output an operation signal OP_S, a row address RADD, a source line control signal SL_S, a page buffer control signal PB_S, and a column address CADD in response to the command CMD and the address ADD.

The voltage generating circuit 31 may generate and output various operation voltages used for the program operation, the read operation, and the erase operation in response to the operation signal OP_S. The operation voltages output from the voltage generating circuit 31 may be transmitted to the pass circuit 40 through a plurality of global lines GLL.

The block decoder 33 may output a block select signal in response to the row address RADD. The block select signal output from the block decoder 33 may be transmitted to the pass circuit 40 through a block select line BSEL.

The pass circuit 40 may transfer the operation voltages transmitted to the plurality of global lines GLL to the drain select line DSL, the word line WL, and the source select line SSL in response to the block select signal transmitted to the block select line BSEL.

The column decoder 35 may transmit the data DATA input from the input/output circuit 21 to the page buffer 37 or transmit the data DATA stored in the page buffer 37 to the input/output circuit 21, in response to the column address CADD. The column decoder 35 may exchange the data DATA with the input/output circuit 21 through a column line CL. The column decoder 35 may exchange the data DATA with the page buffer 37 through a data line DL.

The page buffer 37 may store read data received through a bit line BL in response to the page buffer control signal PB_S. The page buffer 37 may sense a voltage or a current of the bit line BL during the read operation. The page buffer 37 may be connected to the memory cell array 10 through the bit line BL.

The source line driver 39 may control a voltage applied to a common source line CSL in response to the source line control signal SL_S. The source line driver 39 may be connected to the memory cell array 10 through the common source line CSL.

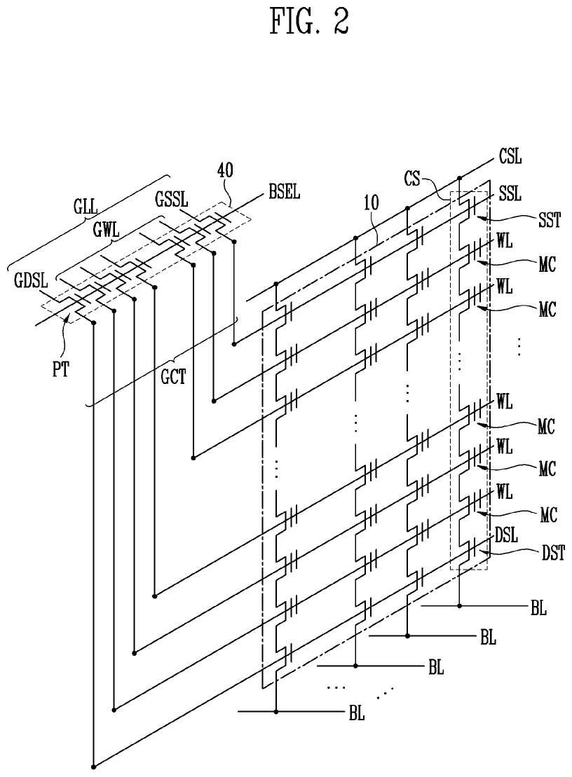

FIG. 2 is a circuit diagram illustrating a memory cell array and a pass circuit according to an embodiment of the present disclosure.

Referring to FIG. 2, the memory cell array 10 may include a plurality of memory cell strings CS. The plurality of memory cell strings CS may be connected to the plurality of bit lines BL and the common source line CSL.

Each memory cell string CS may include at least one source select transistor SST, a plurality of memory cells MC, and at least one drain select transistor DST.

The source select transistor SST may control an electrical connection between the plurality of memory cells MC and the common source line CSL. The drain select transistor DST may control an electrical connection between the plurality of memory cells MC and the bit line BL.

One source select transistor SST may be disposed or two or more source select transistors connected in series may be disposed between the common source line CSL and the plurality of memory cells MC. One drain select transistor DST may be disposed or two or more drain select transistors connected in series may be disposed between each bit line BL and the plurality of memory cells MC of the memory cell string CS corresponding thereto.

A plurality of gates of the plurality of memory cells MC may be respectively connected to the plurality of word lines WL. A gate of the source select transistor SST may be connected to the source select line SSL. A gate of the drain select transistor DST may be connected to the drain select line DSL.

The source select line SSL, the drain select line DSL, and the plurality of word lines WL may be connected to the pass circuit 40. The pass circuit 40 may include a plurality of pass transistors PT. The plurality of pass transistors PT may be respectively connected to a plurality of gate contact plugs GCT. The plurality of gate contact plugs GCT may be respectively connected to the source select line SSL, the drain select line DSL, and the plurality of word lines WL. Each pass transistor PT may be connected to a corresponding gate line among the source select line SSL, the drain select line DSL, and the plurality of word lines WL via a gate contact plug GCT corresponding thereto.

The plurality of pass transistors PT may transfer voltages applied to the plurality of global lines GLL to the source select line SSL, the drain select line DSL, and the plurality of word lines WL in response to the block select signal applied to the block select line BSEL. The plurality of global lines GLL may include a global source select line GSSL, a global drain select line GDSL, and a plurality of global word lines GWL respectively corresponding to the source select line SSL, the drain select line DSL, and the plurality of word lines WL.

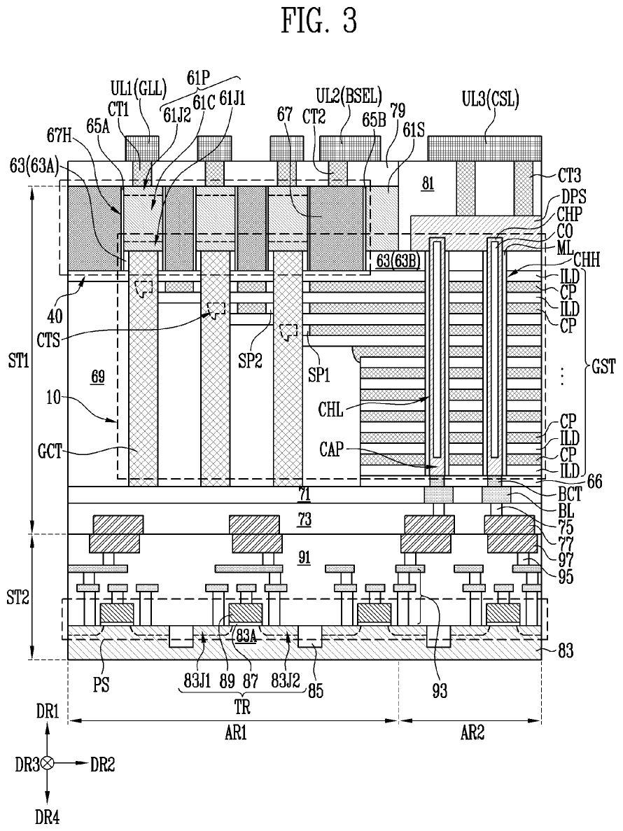

FIGS. 3, 4, 5, 6, 7A, and 7B are diagrams illustrating a semiconductor memory device according to an embodiment of the present disclosure.

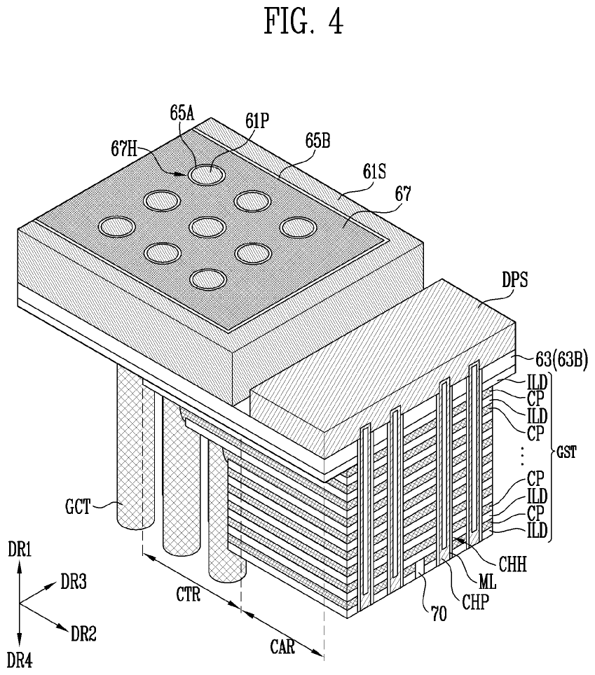

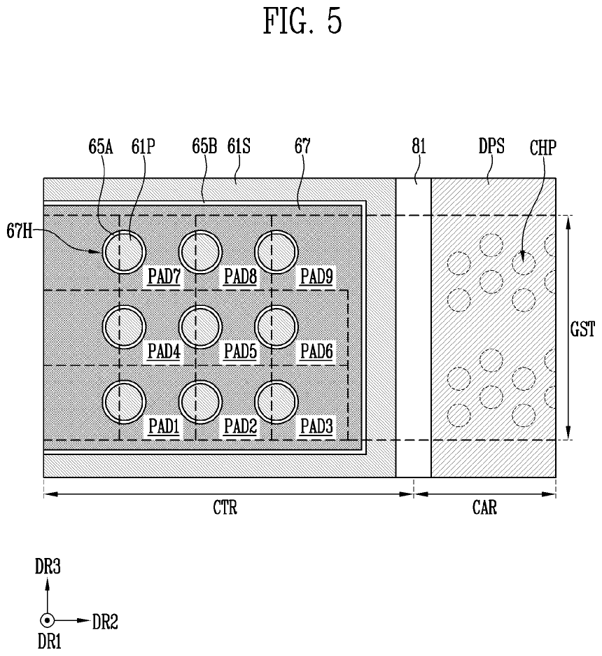

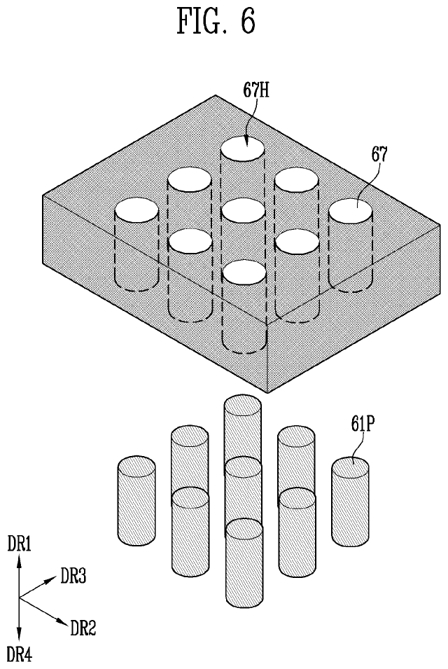

FIG. 3 is a cross-sectional view illustrating a semiconductor memory device according to an embodiment of the present disclosure. FIG. 4 is a perspective view illustrating a memory cell array, a doped semiconductor layer, a gate contact plug, and a pass circuit shown in FIG. 3. FIG. 5 is a plan view illustrating the memory cell array, the doped semiconductor layer, the gate contact plug, and the pass circuit shown in FIG. 3. FIG. 6 is an exploded perspective view illustrating a pass gate and a plurality of active pillars shown in FIG. 3.

Referring to FIG. 3, the semiconductor memory device may include a first structure ST1, a second structure ST2, the doped semiconductor layer DPS, a plurality of contacts CT1 to CT3, and a plurality of upper lines UL1 to UL3. The first structure ST1 may include the pass circuit 40, a plurality of gate contact plugs GCT connected to the pass circuit 40, the memory cell array 10 connected to the plurality of gate contact plugs GCT, the bit line BL connected to the memory cell array 10, and a plurality of first conductive bonding patterns 77. The second structure ST2 may include the peripheral circuit structure PS, a plurality of interconnections 93 connected to the peripheral circuit structure PS, and a plurality of second conductive bonding patterns 97 connected to the plurality of interconnections 93. The peripheral circuit structure PS may include a first region AR1 and a second region AR2.

The pass circuit 40 may include a plurality of pass transistors PT shown in FIG. 2 and comprising the pass gate 67, the plurality of active pillars 61P, and a plurality of first pass gate insulating layers 65A.

The pass gate 67 may be spaced apart from the second structure ST2 including the peripheral circuit structure PS in a first direction DR1. The pass gate 67 may overlap the first region AR1 of the peripheral circuit structure PS. The pass gate 67 may serve as a gate of each of the plurality of pass transistors PT shown in FIG. 2.

Referring to FIGS. 3 to 6, the pass gate 67 may include a plurality of active holes 67H respectively corresponding to the plurality of active pillars 61P. The pass gate 67 may include at least one of the doped semiconductor layer and a metal layer. As an embodiment, the doped semiconductor layer of the pass gate 67 may include a doped silicon layer. As an embodiment, the metal layer of the pass gate 67 may include tungsten, copper, molybdenum, or the like. The pass gate 67 may further include a metal nitride layer. The metal nitride layer may include titanium nitride, tantalum nitride, and the like. The metal nitride layer may be formed along a surface of the metal layer.

The plurality of active pillars 61P may be respectively disposed in the plurality of active holes 67H of the pass gate 67. The plurality of active pillars 61P may include a semiconductor material such as silicon or germanium. Each of the plurality of first pass gate insulating layers 65A may surround a side of the active pillar 61P corresponding thereto. Accordingly, each first pass gate insulating layer 65A may be interposed between the pass gate 67 and the active pillar 61P corresponding thereto.

Referring to FIG. 3, each active pillar 61P may include a channel region 61C, a first junction 61J1, and a second junction 61J2. The channel region 61C of the active pillar 61P may serve as a channel of a pass transistor corresponding thereto, and each of the first junction 61J1 and the second junction 61J2 of the active pillar 61P may serve as a source or a drain of a pass transistor corresponding thereto. Each of the channel region 61C, the first junction 61J1, and the second junction 61J2 may include at least one of an n-type impurity and a p-type impurity. As an embodiment, the channel region 61C may include the p-type impurity as a majority carrier, and the first junction 61J1 and the second junction 61J2 may include the n-type impurity as a majority carrier. The first junction 61J1 may face a gate stack GST of the memory cell array 10, and the second junction 61J2 may face a direction opposite to that of the first junction 61J1. The channel region 61C may be disposed between the first junction 61J1 and the second junction 61J2.

Referring to FIGS. 3 to 5, the memory cell array 10 of the first structure ST1 may include channel pillars CHP extending in the first direction DR1, a memory layer ML surrounding a side of the channel pillar CHP, and the gate stack GST described above. The gate stack GST may be disposed between the pass gate 67 and the peripheral circuit structure PS. The gate stack GST may include a plurality of conductive patterns CP spaced apart from each other in the first direction DR1 and stacked in the first direction DR1. The gate stack GST may further include a plurality of interlayer insulating layers ILD alternately stacked with the plurality of conductive patterns CP in the first direction DR1. Each conductive pattern CP and each interlayer insulating layer ILD may be formed in a plate shape. As an embodiment, each conductive pattern CP and each interlayer insulating layer ILD may include a surface extending in a second direction DR2 and a third direction DR3. The second direction DR2 and the third direction DR3 may be defined as directions in which axes crossing each other face. In addition, each of the second direction DR2 and the third direction DR3 may be defined as a direction toward which a side of each active pillar 61P faces.

The gate stack GST may include a contact region CTR overlapping the pass gate 67 and a cell array region CAR extending from the contact region CTR in the second direction DR2. The cell array region CAR of the gate stack GST may overlap the second region AR2 of the peripheral circuit structure PS.

The plurality of conductive patterns CP and the plurality of interlayer insulating layers ILD of the gate stack GST may be formed in a stepped structure in the contact region CTR. A plurality of ends of the plurality of conductive patterns CP may configure a plurality of pad portions PAD1 to PAD9. The plurality of pad portions PAD1 to PAD9 may correspond to a plurality of steps forming a stepped structure of the gate stack GST. The plurality of pad portions PAD1 to PAD9 may overlap the plurality of active pillars 61P, respectively.

The plurality of conductive patterns CP and the plurality of interlayer insulating layers ILD of the gate stack GST may extend from the contact region CTR to the cell array region CAR so as to overlap the second region AR2 of the peripheral circuit structure PS. The plurality of conductive patterns CP may be used as the drain select line DSL, the plurality of word lines WL, and the source select line SSL shown in FIG. 2. Among the plurality of conductive patterns CP, at least one a conductive pattern adjacent to the peripheral circuit structure PS and a conductive pattern adjacent to the pass gate 67 may be penetrated by a select line separation structure 70 to be separated into select lines, and the remaining conductive patterns may overlap the select line separation structure 70 to be continuously extended without being separated by the select line separation structure 70. For example, among the plurality of conductive patterns CP, the conductive pattern adjacent to the circuit structure PS may be separated into a first drain select line and a second drain select line by the select line separation structure 70, and the remaining conductive patterns may be continuously extended to overlap the first and second drain select lines.

The plurality of conductive patterns CP may include at least one of a doped semiconductor layer and a metal layer. The doped semiconductor layer of each conductive pattern CP may include a doped silicon layer. The metal layer of each conductive pattern CP may include tungsten, copper, molybdenum, or the like. The plurality of conductive patterns CP may further include a metal nitride layer. The metal nitride layer may include titanium nitride, tantalum nitride, and the like. The plurality of interlayer insulating layers ILD may include a silicon oxide layer or the like.

The plurality of conductive patterns CP and the plurality of interlayer insulating layers ILD of the gate stack GST may be penetrated by the plurality of channel holes CHH in the cell array region CAR. The channel pillar CHP may be disposed in each channel hole CHH. The channel pillar CHP may be formed of a semiconductor material. As an embodiment, the channel pillar CHP may include silicon, germanium, or a mixture thereof. A core insulating layer CO may be disposed inside the channel pillar CHP. The core insulating layer CO may include an insulating material such as silicon oxide. The channel pillar CHP may include a channel layer CHL and a capping pattern CAP. The channel layer CHL may be used as a channel region of a memory cell string corresponding thereto and may surround a side of the core insulating layer CO. The channel layer CHL may extend to cover a first surface of the core insulating layer CO facing the first direction DR1. The capping pattern CAP may cover a second surface of the core insulating layer CO facing a fourth direction DR4 opposite to the first direction DR1. The capping pattern CAP may be used as a drain junction of the memory cell string. The capping pattern CAP may include at least one of an n-type impurity and a p-type impurity. As an embodiment, the capping pattern CAP may include an n-type impurity as a majority carrier.

The memory layer ML may be disposed between the channel pillar CHP and the gate stack GST. The memory layer ML may include a blocking insulating layer between the channel pillar CHP and the gate stack GST, a data storage layer between the blocking insulating layer and the channel pillar CHP, and a tunnel insulating layer between the data storage layer and the channel pillar CHP. The blocking insulating layer may include an insulating material capable of blocking a charge. The tunnel insulating layer may include an insulating material capable of charge tunneling. The blocking insulating layer may include an insulating layer having a dielectric constant higher than that of the tunnel insulating layer. The data storage layer may be formed of a material layer capable of storing changed data using Fowler Nordheim tunneling. As an embodiment, the data storage layer may be formed of a charge trap insulating layer or an insulating layer including a conductive nano-dot. The charge trap insulating layer may include a silicon nitride layer. The present disclosure is not limited thereto, and the data storage layer may be formed of a material layer capable of storing information based on an operation principle other than Fowler Nordheim tunneling. As an embodiment, the data storage layer may include a phase change material layer, a ferroelectric layer, and the like. In this case, the channel pillar CHP may be replaced with a pillar shape electrode structure.

The plurality of gate contact plugs GCT may be respectively connected to the plurality of active pillars 61P. As an embodiment, each gate contact plug GCT may contact the first junction 61J1 of the active pillar 61P corresponding thereto and extend in the fourth direction DR4. The plurality of gate contact plugs GCT may pass through the gate stack GST in the contact region CTR of the gate stack GST. Each gate contact plug GCT may include at least one of a doped semiconductor layer and a metal layer. The doped semiconductor layer of the gate contact plug GCT may include a doped silicon layer. The metal layer of the gate contact plug GCT may include tungsten, copper, molybdenum, or the like. Each gate contact plug GCT may further include a metal nitride layer. The metal nitride layer may include titanium nitride, tantalum nitride, and the like. The metal nitride layer may be formed along a surface of the metal layer.

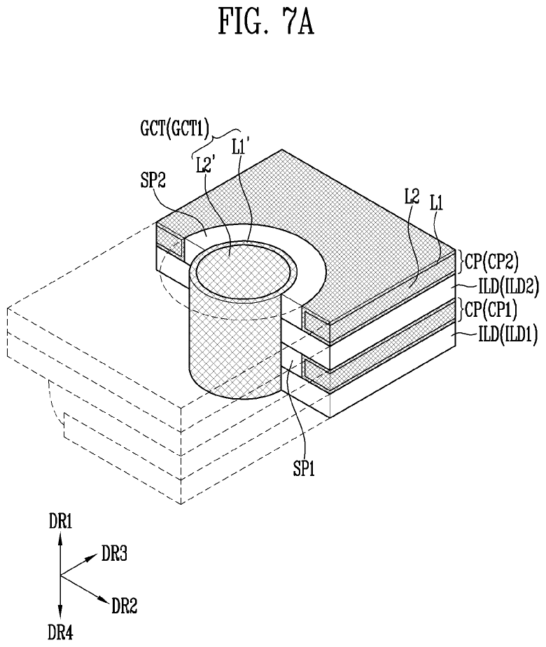

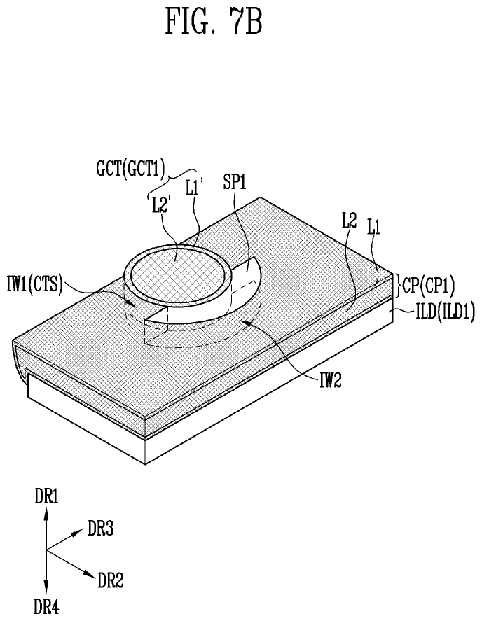

FIGS. 7A and 7B are perspective views illustrating a portion of the gate stack and a portion of the gate contact plug shown in FIG. 3. FIG. 7A illustrates a portion of configurations of the semiconductor memory device through perspective for convenience of recognition.

Referring to FIGS. 3, 7A, and 7B, the plurality of gate contact plugs GCT may pass through the plurality of pad portions PAD1 to PAD9, respectively. Each gate contact plug GCT may form a contact surface CTS with a pad portion of a corresponding conductive pattern among the plurality of pad portions PAD1 to PAD9 of the plurality of conductive patterns CP. For example, the plurality of gate contact plugs GCT may include a first gate contact plug GCT1. The plurality of conductive patterns CP may include a first conductive pattern CP1 and a second conductive pattern CP2 adjacent to each other in the first direction DR1. The first conductive pattern CP1 may form the contact surface CTS with the first gate contact plug GCT1, and the second conductive pattern CP2 may be insulated from the first gate contact plug GCT1.

A first insulating spacer SP1 and at least one second insulating spacer SP2 may be buried in each of the plurality of conductive patterns CP. The first insulating spacer SP1 may be adjacent to the contact surface CTS between each conductive pattern CP and the gate contact plug GCT corresponding thereto, and may surround a portion of a side of the gate contact plug GCT. The second insulating spacer SP2 may be interposed between the conductive pattern CP and the gate contact plug GCT requiring mutual insulation, and may be formed in an annular shape to surround a side of the gate contact plug GCT. For example, the first insulating spacer SP1 may be adjacent to the contact surface CTS between the first gate contact plug GCT1 and the first conductive pattern CP1, and may surround a portion of a side of the first gate contact plug GCT1. The second insulating spacer SP2 may be interposed between the first gate contact plug GCT1 and the second conductive pattern CP2 and may surround a side of the first gate contact plug GCT1 in an annular shape.

Each conductive pattern (for example, CP1) may include a first inner sidewall IW1 and a second inner sidewall IW2. The first inner sidewall IW1 of each conductive pattern (for example, CP1) may form a contact surface CTS with a gate contact plug (for example, GCT1) corresponding thereto. The second inner sidewall IW2 may extend from the first inner sidewall IW1 along a side of the first insulating spacer SP1.

Each of the first insulating spacer SP1 and the second insulating spacer SP2 may be interposed between interlayer insulating layers ILD adjacent in the first direction DR1. For example, the plurality of interlayer insulating layers ILD may include a first interlayer insulating layer ILD1 and a second interlayer insulating layer ILD2 adjacent to each other in the first direction DR1 with the first conductive pattern CP1 interposed therebetween, and the first insulating spacer SP1 may be interposed between the first interlayer insulating layer ILD1 and the second interlayer insulating layer ILD2.

Each of the plurality of conductive patterns CP may include a metal nitride layer L1 and a metal layer L2, and each of the plurality of gate contact plugs GCT may include a metal nitride layer L1′ and a metal layer L2′. In this case, the contact surface CTS may be defined by contact between the metal nitride layer L1 of the conductive pattern CP and the metal nitride layer L1′ of the gate contact plug GCT.

Referring to FIGS. 3 to 5, the first structure ST1 may further include a semiconductor pattern 61S and a second pass gate insulating layer 65B. The semiconductor pattern 61S may be disposed at a level where the plurality of active pillars 61P are disposed. The semiconductor pattern 61S may include the same semiconductor material as the plurality of active pillars 61P. The semiconductor pattern 61S may include an impurity of the same conductivity as the channel region 61C of each active pillar 61P. The semiconductor pattern 61S may be spaced apart from the pass gate 67 and may surround a sidewall of the pass gate 67. The second pass gate insulating layer 65B may be interposed between the semiconductor pattern 61S and the pass gate 67.

The first structure ST1 may further include an interposition insulating layer 63 interposed between the semiconductor pattern 61S and each of the plurality of active pillars 61P and the gate stack GST. The interposition insulating layer 63 may include a plurality of first interposition portions 63A and a second interposition portion 63B. The plurality of first interposition portions 63A may be disposed between the gate stack GST and the plurality of active pillars 61P. The second interposition portion 63B may be disposed between the gate stack GST and the semiconductor pattern 61S. The second interposition portion 63B of the interposition insulating layer 63 may extend to overlap the cell array region CAR of the gate stack GST and the second region AR2 of the peripheral circuit structure PS. The pass gate 67 may extend between the plurality of first interposition portions 63A and the second interposition portion 63B to separate the plurality of first interposition portions 63A and the second interposition portion 63B from each other.

The plurality of gate contact plugs GCT may respectively pass through the plurality of first interposition portions 63A of the interposition insulating layer 63 and contact the plurality of active pillars 61P. The plurality of conductive patterns CP may be electrically connected to the plurality of active pillars 61P of the pass circuit 40 by the plurality of gate contact plugs GCT.

The channel pillar CHP and the memory layer ML may extend to pass through the second interposition portion 63B of the interposition insulating layer 63. The channel pillar CHP may protrude in the first direction DR1 in comparison with the second interposition portion 63B of the interposition insulating layer 63 and the memory layer ML. A protrusion of the channel pillar CHP may contact the doped semiconductor layer DPS.

The doped semiconductor layer DPS may be spaced apart from the peripheral circuit structure PS in the first direction DR1 and may overlap the second region AR2 of the peripheral circuit structure PS. The doped semiconductor layer DPS may overlap the plurality of conductive patterns CP and the plurality of interlayer insulating layers ILD of the gate stack GST with the second interposition portion 63B of the interposition insulating layer 63 interposed therebetween. The doped semiconductor layer DPS may be spaced apart from the plurality of active pillars 61P and the pass gate 67 in the second direction DR2. The doped semiconductor layer DPS may surround the protrusion of the channel pillar CHP protruding in the first direction DR1 in comparison with the memory layer ML. The doped semiconductor layer DPS may extend in the second direction DR2 and the third direction DR3 to overlap the cell array region CAR of the gate stack GST. A plurality of channel pillars CHP may be disposed between the doped semiconductor layer DPS and the peripheral circuit structure PS, and the plurality of channel pillars CHP may be connected to the doped semiconductor layer DPS in parallel.

The doped semiconductor layer DPS may include at least one of an n-type impurity and a p-type impurity. The doped semiconductor layer DPS may be used as at least one of a source region and a well region. As an embodiment, the doped semiconductor layer DPS may be provided as the source region including an n-type impurity as a majority carrier. An embodiment of the present disclosure is not limited thereto. As another embodiment, the doped semiconductor layer DPS may include at least one of a first conductivity type doped region including an n-type impurity as a majority carrier and a second conductivity type doped region including a p-type impurity as a majority carrier. The first conductivity type doped region may serve as the source region, and the second conductivity type doped region may serve as the well region.

Referring to FIG. 3, the pass gate 67 and the doped semiconductor layer DPS may be covered with a first upper insulating layer 79 and a second upper insulating layer 81, respectively. The first upper insulating layer 79 may extend to cover the plurality of active pillars 61P and the semiconductor pattern 61S. As shown in FIGS. 3 and 5, the second upper insulating layer 81 may extend between the semiconductor pattern 61S and the doped semiconductor layer DPS.

Referring to FIG. 3, the plurality of upper lines UL1 to UL3 may be disposed over any one of the first upper insulating layer 79 and the second upper insulating layer 81. The plurality of upper lines UL1 to UL3 are conductive lines transmitting an electrical signal, and may include first to third upper lines UL1 to UL3. The first upper line UL1 may be connected to the active pillar 61P corresponding thereto and may be used as the global line GLL. The second upper line UL2 may be connected to the pass gate 67 and may be used as the block select line BSEL. The third upper line UL3 may be connected to the doped semiconductor layer DPS and may be used as the common source line CSL.

The plurality of contacts CT1 to CT3 may be formed of a conductive material and may include first to third contacts CT1 to CT3 respectively connected to the first to third upper lines UL1 to UL3. The first contact CT1 may contact the second junction 61J2 of the active pillar 61P corresponding thereto, and pass through the first upper insulating layer 79 to connect the second junction 61J2 to the first upper line UL1. The second contact CT2 may contact the pass gate 67, and pass through the first upper insulating layer 79 to connect the pass gate 67 to the second upper line UL2. The third contact CT3 may contact the doped semiconductor layer DPS, and pass through the second upper insulating layer 81 to connect the doped semiconductor layer DPS to the third upper line UL3.

The channel pillar CHP of the first structure ST1 may be disposed between the doped semiconductor layer DPS and the bit line BL. The bit line BL may be formed of a conductive material and may be connected to the channel pillar CHP corresponding thereto. As an embodiment, the bit line BL may be connected to the capping pattern CAP of the channel pillar CHP corresponding thereto via a conductive bit line contact BCT.

The conductive bit line contact BCT may pass through a buffer insulating layer 66 interposed between the gate stack GST and the bit line BL. The bit line BL may pass through an insulating layer 71 between the buffer insulating layer 66 and the second structure ST2. The insulating layer 71 may extend between the gate stack GST and the first region AR1 of the peripheral circuit structure PS. A filling insulating layer 69 may be disposed between the stepped structure of the gate stack GST and the insulating layer 71. The plurality of gate contact plugs GCT may extend to pass through the filling insulating layer 69.

The plurality of first conductive bonding patterns 77 of the first structure ST1 may be disposed in the first insulating structure 73. The first insulating structure 73 may be interposed between the second structure ST2 and the insulating layer 71. The first insulating structure 73 may include multiple layers of insulating layers. The plurality of first conductive bonding patterns 77 may include a metal such as copper. A portion of the plurality of first conductive bonding patterns 77 may be connected to the bit line BL. As an embodiment, the bit line BL may be connected to a portion of the plurality of first conductive bonding patterns 77 via a first conductive bonding contact 75. The first conductive bonding contact 75 may be disposed in the first insulating structure 73 between the bit line BL and the first conductive bonding pattern 77 corresponding thereto.

The peripheral circuit structure PS of the second structure ST2 may include a plurality of transistors TR formed on a peripheral circuit substrate 83. The peripheral circuit substrate 83 may be a semiconductor substrate of silicon, germanium, or the like. A portion of the plurality of transistors TR may configure the page buffer 37 shown in FIG. 1.

Each transistor TR may include a gate insulating layer 87, a gate electrode 89, a source junction 83J1, and a drain junction 83J2. The gate insulating layer 87 and the gate electrode 89 may be stacked over an active region 83A of the peripheral circuit substrate 83. The active region 83A of the peripheral circuit substrate 83 may be partitioned by an isolation layer 85. The source junction 83J1 and the drain junction 8312 may be formed in the active region 83A of both sides of the gate electrode 89.

The peripheral circuit structure PS may be covered with a second insulating structure 91. The second insulating structure 91 may include multiple layers of insulating layers.

The plurality of interconnections 93 of the second structure ST2 may be disposed in the second insulating structure 91. The plurality of interconnections 93 may include a plurality of conductive patterns connected to the gate electrode 89, the source junction 83J1, and the drain junction 83J2. The plurality of interconnections 93 may be connected to the plurality of second conductive bonding patterns 97 via a plurality of second conductive bonding contacts 95.

The plurality of second conductive bonding patterns 97 may include a metal such as copper. Each of the plurality of second conductive bonding contacts 95 may be disposed between the second conductive bonding pattern 97 corresponding thereto and the interconnection 93 and may be disposed in the second insulating structure 91.

The plurality of second conductive bonding patterns 97 may be bonded to the plurality of first conductive bonding patterns 77 to be structurally and electrically connected to the plurality of first conductive bonding patterns 77. A portion of the plurality of second conductive bonding patterns 97 may be connected to a transistor of the page buffer among the plurality of transistors TR. The transistor of the page buffer may be connected to a corresponding second conductive bonding pattern 97 via the second conductive bonding contact 95 and the interconnection 93.

Referring to FIGS. 3 to 6, the pass gate 67 may be used as a plurality of gates of the plurality of pass transistors of the pass circuit 40. Accordingly, the plurality of pass transistors of the pass circuit 40 may be commonly controlled according to an electrical signal applied to the second upper line UL2.

Referring to FIGS. 3 to 6, in an embodiment, because the plurality of active pillars 61P are respectively disposed in the plurality of active holes 67H of the pass gate 67, each of the plurality of pass transistors may be formed in a surrounding gate transistor (SGT) structure. Accordingly, in an embodiment, an area occupied by the plurality of pass transistors may be reduced and an on/off characteristic of each pass transistor may be improved.

Referring to FIG. 3, in an embodiment, because the pass circuit 40 is disposed to overlap the peripheral circuit structure PS with the gate stack GST interposed therebetween, an area allocated to the pass circuit 40 in the peripheral circuit substrate 83 may be reduce. Accordingly, in an embodiment, an integration degree of the semiconductor memory device may be improved.

Referring to FIGS. 3 and 4, the plurality of active pillars 61P of the pass circuit 40 may overlap the contact region CTR of the gate stack GST opened by the doped semiconductor layer DPS. Accordingly, in an embodiment, because the area allocated to the pass circuit 40 may be reduced, the integration degree of the semiconductor memory device may be improved. In addition, the plurality of active pillars 61P of the pass circuit 40 may overlap the plurality of gate contact plugs GCT disposed in the contact region CTR of the gate stack GST. Accordingly, in an embodiment, because the plurality of gate contact plugs GCT and the plurality of active pillars 61P may be directly connected, a connection structure between the plurality of conductive patterns CP and the pass circuit 40 may be simplified.

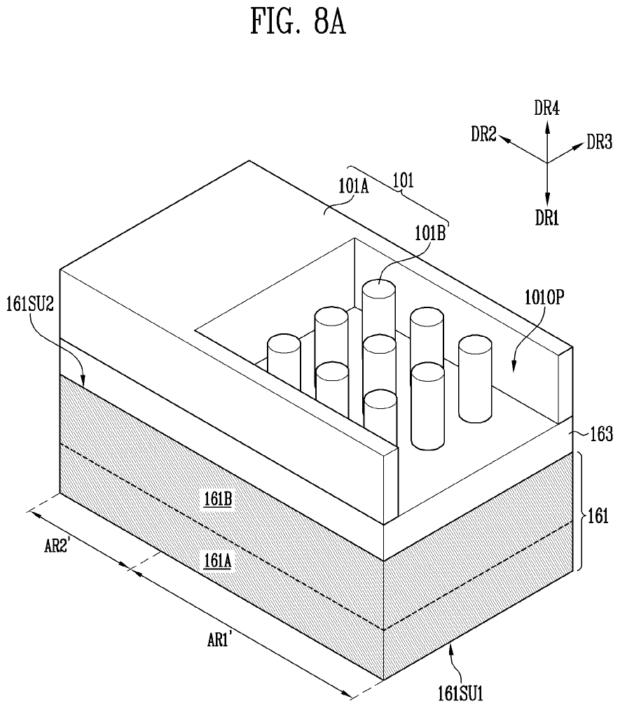

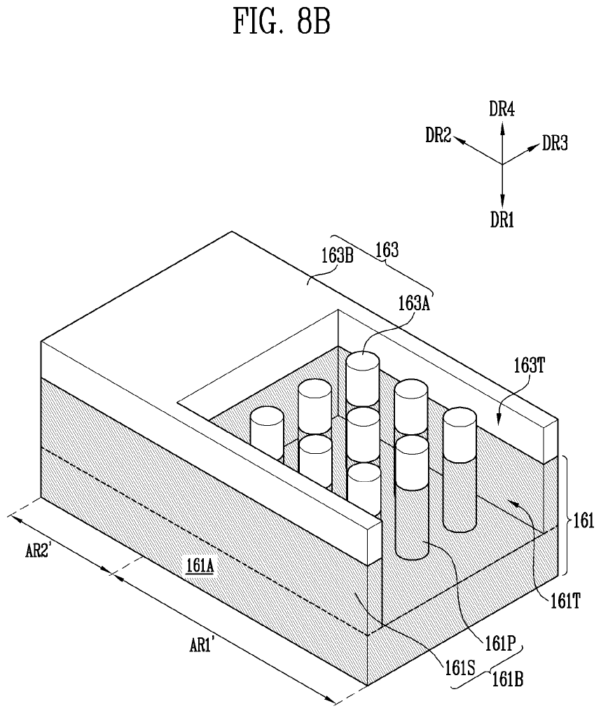

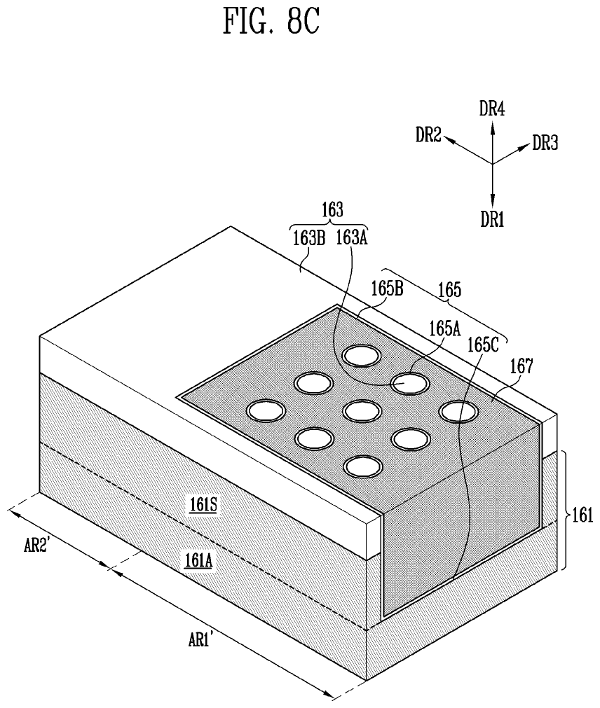

FIGS. 8A to 8C, 9A, 9B, 10A to 10C, 11A to 11D, 12A, 12B, and 13A to 13J are diagrams illustrating a method of manufacturing a semiconductor memory device according to an embodiment of the present disclosure.

FIGS. 8A to 8C are perspective views illustrating a process of forming the plurality of active pillars and the pass gate.

Referring to FIG. 8A, an interposition insulating layer 163 may be formed to cover a second surface 161SU2 of a semiconductor substrate 161 including a first surface 161SU1 and the second surface 161SU2 facing opposite directions. The semiconductor substrate 161 may include a first impurity region 161A adjacent to the first surface 161SU1 and a second impurity region 161B adjacent to the second surface SU2. The first impurity region 161A and the second impurity region 161B may include at least one of an n-type impurity and a p-type impurity. As an embodiment, the first impurity region 161A and the second impurity region 161B may include a p-type impurity as a majority carrier. The first impurity region 161A may include a conductive impurity of a concentration higher than that of the second impurity region 161B so that the first impurity region 161A may be selectively removed later. As an embodiment, the first impurity region 161A may include a p-type impurity at a concentration higher than that of the second impurity region 161B.

A direction toward which the first surface 161SU1 of the semiconductor substrate 161 faces may be defined as the first direction DR1, each of the first impurity region 161A and the second impurity region 161B of the semiconductor substrate 161 may extend in the second direction DR2 and the third direction DR3, and a direction toward which the second surface 161SU2 of the semiconductor substrate 161 faces may be defined as the fourth direction DR4. The first direction DR1 and the fourth direction DR4 may correspond to a −Z-axis direction and a +Z-axis direction, respectively, and the second direction DR2 and the third direction DR3 may correspond to an X-axis direction and a Y-axis direction, respectively.

The semiconductor substrate 161 may include a first region AR1′ and a second region AR2′. The second region AR2′ of the semiconductor substrate 161 may extend from the first region AR1′ in the second direction DR2. The first impurity region 161A and the second impurity region 161B may be formed in the first region AR1′ and the second region AR2′ of the semiconductor substrate 161, respectively.

A first mask pattern 101 may be formed over the interposition insulating layer 163. The first mask pattern 101 may include a first mask portion 101A and a plurality of second mask portions 101B. The first mask portion 101A may have a first opening 101OP, and the plurality of second mask portions 101B may be disposed in the first opening 101OP. The first opening 101OP and the plurality of second mask portions 101B may overlap the first region AR1′ of the semiconductor substrate 161.

Referring to FIG. 8B, the interposition insulating layer 163 and the first region AR1′ of the semiconductor substrate 161 may be etched by an etching process using the first mask pattern 101 shown in FIG. 8A as an etch barrier.

The interposition insulating layer 163 may be separated into a plurality of first interposition portions 163A and second interposing portions 163B by the etching process of the interposition insulating layer 163. A first trench 163T surrounded by the second interposition portion 163B may be defined by partially etching the interposition insulating layer 163. The plurality of first interposition portions 163A may be separated from each other in the first trench 163T. The plurality of first interposition portions 163A may be defined in a region corresponding to the plurality of second mask portions 101B of the first mask pattern 101 shown in FIG. 8A, and the second interposition portion 163B may be defined in a region corresponding to the first mask portion 101A of the first mask pattern 101 shown in FIG. 8A.

The second impurity region 161B of the semiconductor substrate 161 may be etched by the etching process for the first region AR1′ of the semiconductor substrate 161. Therefore, a second trench 161T may be defined in the semiconductor substrate 161 and a plurality of active pillars 161P may be defined. The second trench 161T may be formed in a region corresponding to the first opening 101OP of the first mask pattern 101 shown in FIG. 8A, and the plurality of active pillars 161P may be formed in a region corresponding to the plurality of second mask portions 101B of the first mask pattern 101 shown in FIG. 8A. A semiconductor pattern 161S may be defined in a region corresponding to the first mask portion 101A of the first mask pattern 101 shown in FIG. 8A. The first mask pattern 101 shown in FIG. 8A may be removed after forming the plurality of active pillars 161P and the second trench 161T.

The plurality of active pillars 161P may be formed between the first impurity region 161A of the semiconductor substrate 161 and the plurality of first interposition portions 163A. The plurality of active pillars 161P may be spaced apart from each other in the second trench 161T. The semiconductor pattern 161S may be formed between the first impurity region 161A of the semiconductor substrate 161 and the second interposition portion 163B.

Referring to FIG. 8C, an insulating layer 165 may be formed along a surface of each of the first trench 163T and the second trench 161T shown in FIG. 8B. The insulating layer 165 may extend along a surface of each of the plurality of first interposition portions 163A of the interposition insulating layer 163 and the plurality of active pillars 161P shown in FIG. 8B. The insulating layer 165 may be formed by depositing an insulating layer such as an oxide layer or by using an oxidation process. The insulating layer 165 may include a first vertical portion 165A, a second vertical portion 165B, and a horizontal portion 165C. The first vertical portion 165A of the insulating layer 165 may surround a side of each of the plurality of first interposition portions 163A of the interposition insulating layer 163 and a side of each of the plurality of active pillars 161P shown in FIG. 8B. The second vertical portion 165B of the insulating layer 165 may extend along an inner wall of the first trench 163T shown in FIG. 8B and an inner wall of the second trench 161T shown in FIG. 8B. The horizontal portion 165C may extend along a bottom surface of the second trench 161T shown in FIG. 8B.

Subsequently, a pass gate 167 may be formed. The pass gate 167 may be formed inside the first trench 163T and the second trench 161T shown in FIG. 8B. The first trench 163T and the second trench 161T may include a region opened by the insulating layer 165, the plurality of active pillars 161P, and the plurality of first interposition portions 163A of the interposition insulating layer 163. The pass gate 167 may fill the opened region of the first trench 163T and the second trench 161T. The pass gate 167 may extend in the fourth direction DR4 to surround not only a side of the plurality of active pillars 161P shown in FIG. 8B with the insulating layer 165 interposed therebetween but also a side of the plurality of first interposition portions 163A of the insulating layer 163 with the insulating layer 165 interposed therebetween. According to this, in an embodiment, because the pass gate 167 may be formed to be thicker in the fourth direction DR4 than the active pillar 161P, a sheet resistance of the pass gate 167 may be reduced. The pass gate 167 may include at least one of a doped semiconductor layer and a metal layer. The pass gate 167 may further include a metal nitride layer in addition to the metal layer.

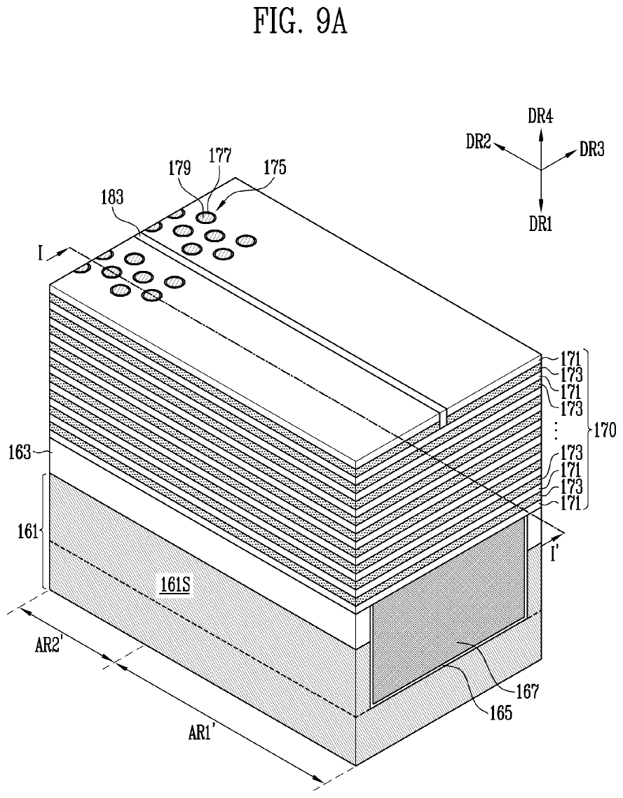

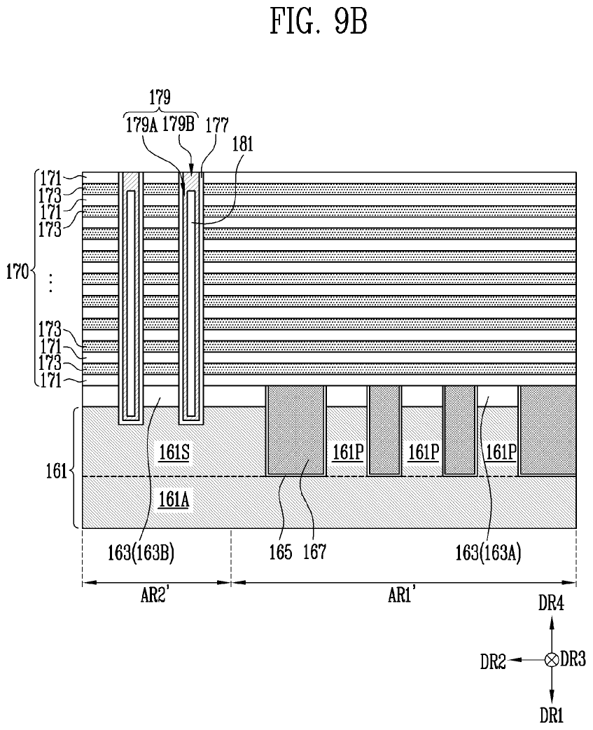

FIGS. 9A and 9B are perspective and cross-sectional views illustrating a process of forming a preliminary stack, the memory layer, and the channel pillar. FIG. 9B is a cross-sectional view taken along a line I-I′ shown in FIG. 9A.

Referring to FIGS. 9A and 9B, the preliminary stack 170 may be formed to overlap the pass gate 167 and the semiconductor substrate 161 including the semiconductor pattern 161S and the plurality of active pillars 161P. The preliminary stack 170 may be formed by alternately stacking a plurality of first material layers 171 and a plurality of second material layers 173 over the interposition insulating layer 163 in the fourth direction DR4.

The plurality of second material layers 173 may be formed of a material having an etch selectivity with respect to the plurality of first material layers 171. As an embodiment, the plurality of first material layers 171 may include an insulating material such as a silicon oxide layer and a silicon oxynitride layer, and the plurality of second material layers 173 may include a sacrificial insulating material such as a silicon nitride layer.

Subsequently, the second region AR2′ of the semiconductor substrate 161 may be exposed by etching a portion of each of the plurality of first material layers 171, the plurality of second material layers 173, and the second interposition portion 163B of the interposition insulating layer 163 overlapping the second region AR2′ of the semiconductor substrate 161. Thereafter, the second region AR2′ of the semiconductor substrate 161 may be etched. At this time, a portion of the semiconductor pattern 161S may be etched in the second region AR2′ of the semiconductor substrate 161. Thus, a plurality of channel holes 175 may be formed. Each channel hole 175 may pass through the preliminary stack 170 and extend into the semiconductor pattern 161S disposed in the second region AR2′ of the semiconductor substrate 161.

Thereafter, the memory layer 177 may be formed along a surface of each channel hole 175. As described with reference to FIGS. 3 to 5, the memory layer 177 may include the blocking insulating layer, the data storage layer, and the tunnel insulating layer. Subsequently, the channel pillar 179 may be formed in the channel hole 175 opened by the memory layer 177.

As an embodiment, forming the channel pillar 179 may include forming a channel layer 179A by depositing a semiconductor material such as silicon or germanium on a surface of the memory layer 177, forming a core insulating layer 181 in the channel hole 175 opened by the channel layer 179A, opening a portion of the channel hole 175 by removing a portion of the core insulating layer 181, and filling a portion of the opened channel hole 175 with the capping pattern 179B. The capping pattern 179B may include a doped semiconductor material.

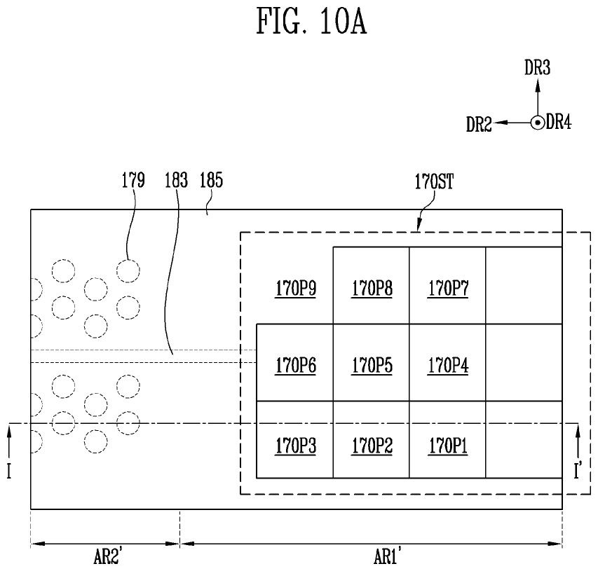

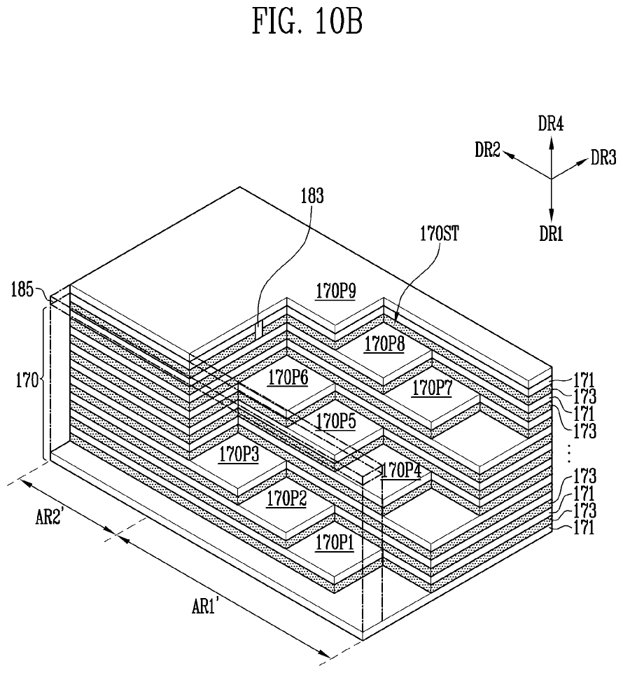

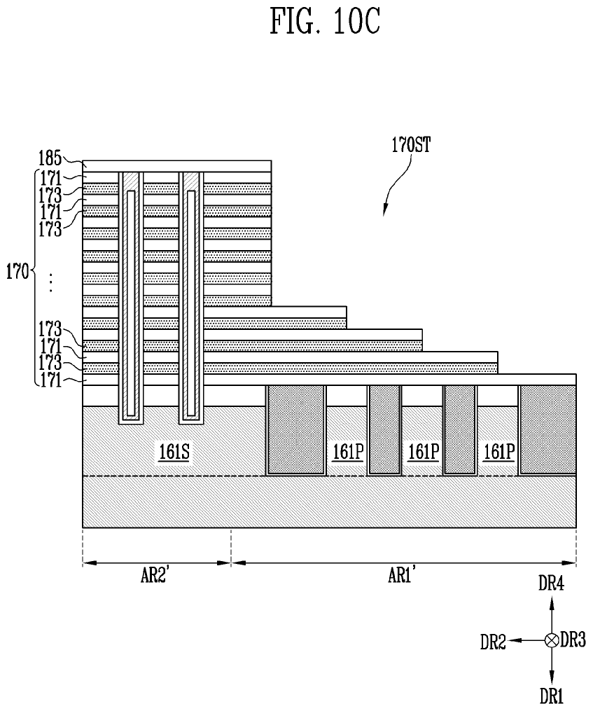

FIGS. 10A to 10C are a plan view, a perspective view, and a cross-sectional view illustrating a process of forming the stepped structure and the buffer insulating layer. FIG. 10B is a perspective view of the preliminary stack illustrating a portion of each of the buffer insulating layer, the plurality of first material layers, and the plurality of second material layers through perspective for convenience of recognition for the stepped structure, and FIG. 10C is a cross-sectional view taken along a line I-I′ shown in FIG. 10A.

Referring to FIGS. 10A to 10C, a select line separation structure 183 passing through at least one layer of second material layer 173 of the preliminary stack 170 may be formed. The select line separation structure 183 may be formed of an insulating material.

Subsequently, the buffer insulating layer 185 may be formed over the preliminary stack 170. The buffer insulating layer 185 may include an oxide such as a silicon oxide layer. Thereafter, an etching process for forming the stepped structure 170ST may be performed. Forming the stepped structure 170ST may include forming a mask layer (not shown) over the buffer insulating layer 185 and etching a portion of each of the buffer insulating layer 185, the plurality of first material layers 171, and the plurality of second material layers 173, by an etching process using the mask layer as an etch barrier. Etching a portion of the plurality of first material layers 171 and a portion of the plurality of second material layers 173 may include a trimming process of reducing a size of the mask layer and an etching process for an exposed region of the plurality of first material layers 171 and an exposed region of the plurality of second material layers 173. The trimming process and the etching process may be repeated until a plurality of pad portions 170P1 to 170P9 are formed. The mask layer may be removed after forming the stepped structure 170ST.

The plurality of pad portions 170P1 to 170P9 may be arranged at different heights and respectively overlap the plurality of active pillars 161P. Each of the plurality of pad portions 170P1 to 170P9 may be configured of a pair of first material layers 171 and second material layers 173 corresponding thereto. The plurality of pad portions 170P1 to 170P9 may correspond to a plurality of steps forming the stepped structure 170ST of the preliminary stack 170.

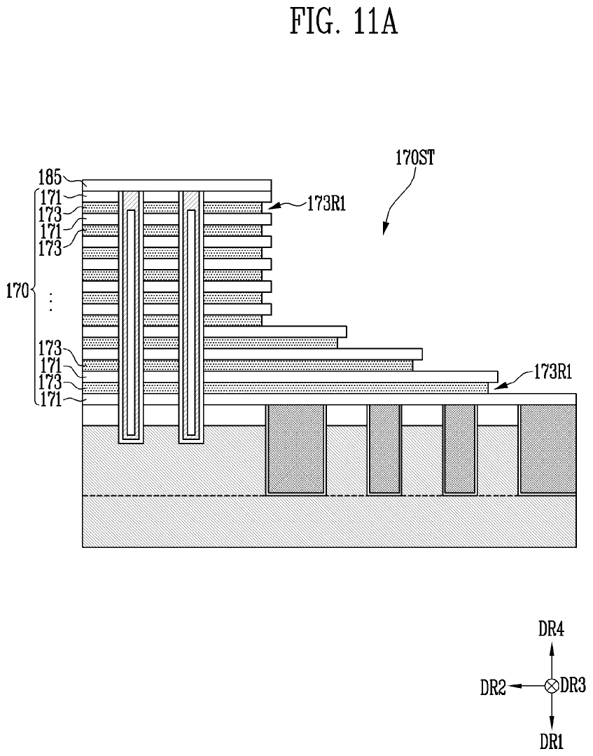

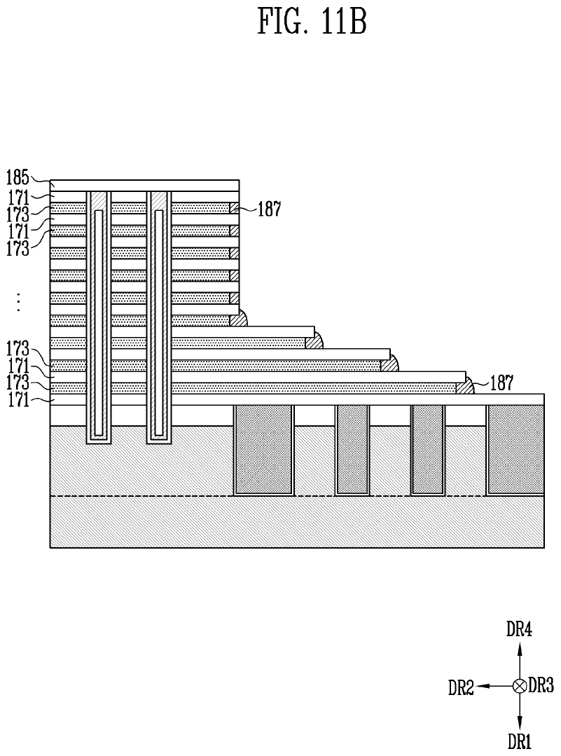

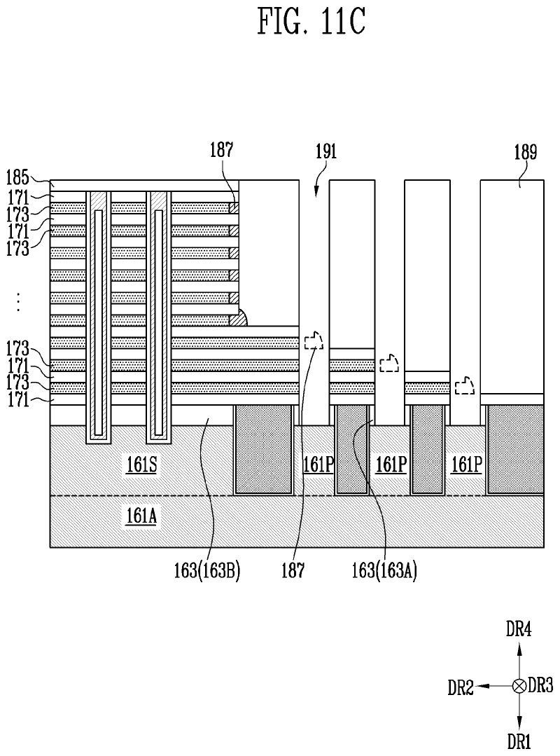

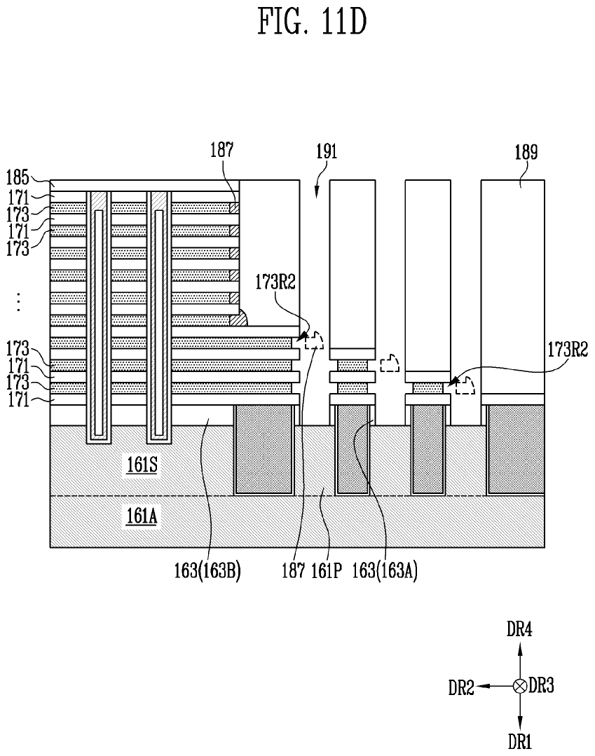

FIGS. 11A to 11D are cross-sectional views illustrating a process of replacing the plurality of second material layers with a plurality of third material layers and a process of forming a plurality of contact holes.

Referring to FIG. 11A, a plurality of first recess regions 173R1 may be formed by etching a portion of the plurality of second material layers 173 from an edge of the stepped structure 170ST in the preliminary stack 170. The plurality of first recess regions 173R1 may be formed by etching a portion of the plurality of second material layers 173 corresponding to the plurality of pad portions 170P1 to 170P9 shown in FIG. 10B. The plurality of first recess regions 173R1 may be defined between the plurality of first material layers 171 adjacent in the fourth direction DR4.

Referring to FIG. 11B, the plurality of first recess regions 173R1 shown in FIG. 11A may be filled with the plurality of third material layers 187. The plurality of third material layers 187 may include a material having an etch selectivity with respect to the plurality of first material layers 171 and the plurality of second material layers 173. As an embodiment, a process of forming the plurality of third material layers 187 may include forming a silicon layer to fill the plurality of first recess regions 173R1 shown in FIG. 11A and removing a portion of the silicon layer using an etching process such as etch-back so that the silicon layer is separated into the plurality of third material layers 187.

Referring to FIG. 11C, a filling insulating layer 189 may be formed to cover the plurality of third material layers 187 and the plurality of pad portions 170P1 to 170P9 described with reference to FIG. 10B. The filling insulating layer 189 may include an oxide such as a silicon oxide layer.

Subsequently, a portion each of the filling insulating layer 189, the plurality of first material layers 171, the plurality of second material layers 170, the plurality of third material layers 187, and the plurality of first interposition portions 163A of the plurality of interposition insulating layer 163 may be etched. Thus, the plurality of contact holes 191 exposing each of the plurality of active pillars 161P may be formed.

Referring to FIG. 11D, a portion of each of the plurality of second material layers 173 may be etched through the plurality of contact holes 191. Thus, a plurality of second recess regions 173R2 may be defined. Each of the plurality of second recess regions 173R2 may be defined between the first material layers 171 adjacent in the fourth direction DR4.

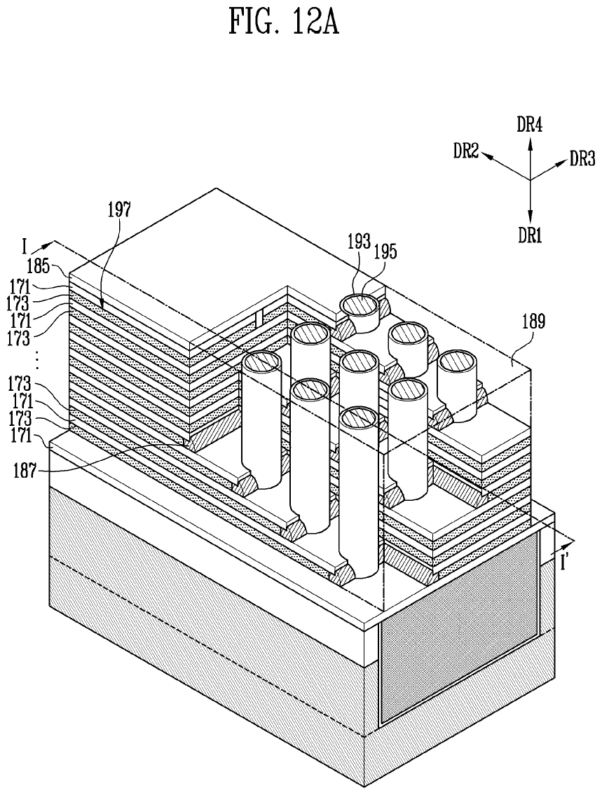

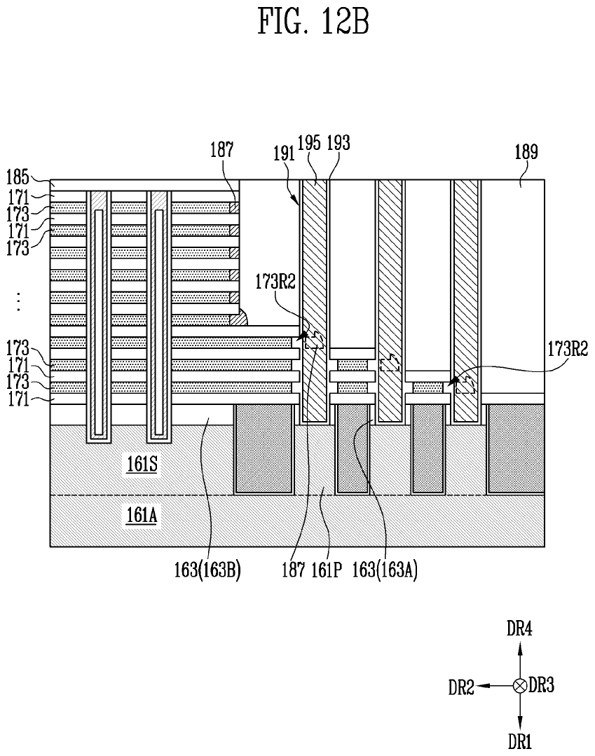

FIGS. 12A and 12B are perspective and cross-sectional views illustrating a process of forming a spacer layer, a plurality of fourth material layers, and the slit. FIG. 12A is a perspective view illustrating the filling insulating layer through perspective for convenience recognition for the spacer layer and the plurality of fourth material layers. FIG. 12B is a cross-sectional view taken along a line I-I′ shown in FIG. 12A.

Referring to FIGS. 12A and 12B, the spacer layer 193 may be formed inside each of the plurality of contact holes 191 to fill the plurality of second recess regions 173R2. The spacer layer 193 may include an insulating material having an etch selectivity with respect to the plurality of second material layers 173 and the plurality of third material layers 187. As an embodiment, the spacer layer 193 may include an oxide such as a silicon oxide layer.

The spacer layer 193 may extend along a surface of each of the plurality of contact holes 191. A central region of each of the plurality of contact holes 191 may be opened without being filled with the spacer layer 193.

Thereafter, the central region of each of the plurality of contact holes 191 opened by the spacer layer 193 may be filled with the fourth material layer 195. The fourth material layer 195 may include a material having an etch selectivity with respect to the spacer layer 193. As an embodiment, the fourth material layer 195 may include silicon. The spacer layer 193 may be interposed between each third material layer 187 and the fourth material layer 195 corresponding thereto.

Subsequently, the slit 197 may be formed by etching the buffer insulating layer 185, the filling insulating layer 189, the plurality of first material layers 171, the plurality of second material layers 173, and the plurality of third material layers 187. The slit 197 may extend in the second direction DR2. A side of each of the plurality of second material layers 173 and the plurality of third material layers 187 may be exposed by the slit 197.

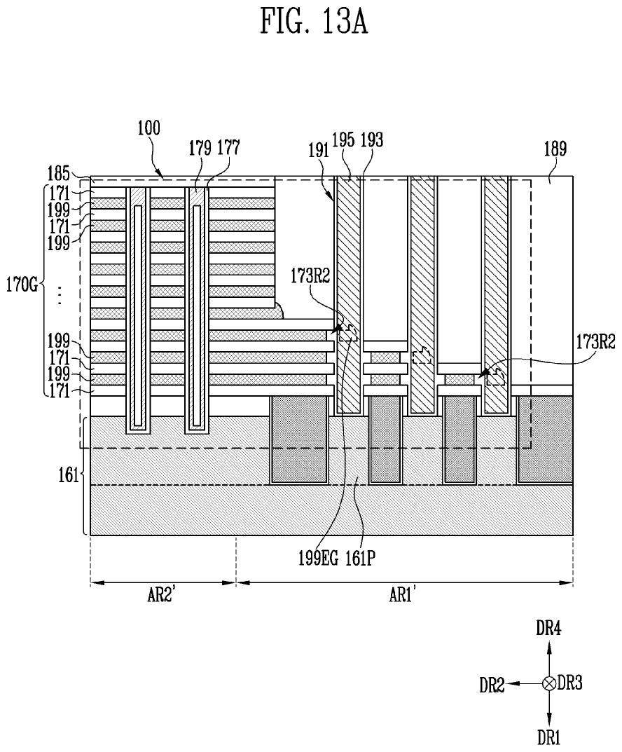

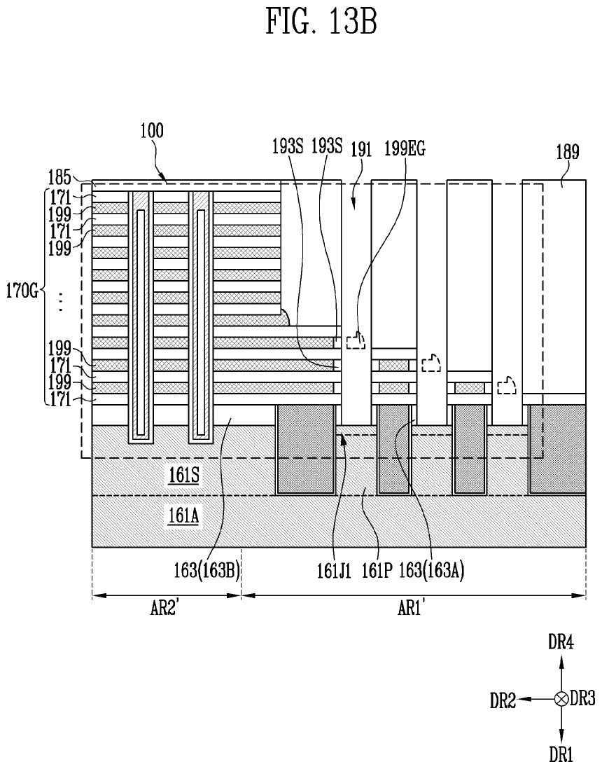

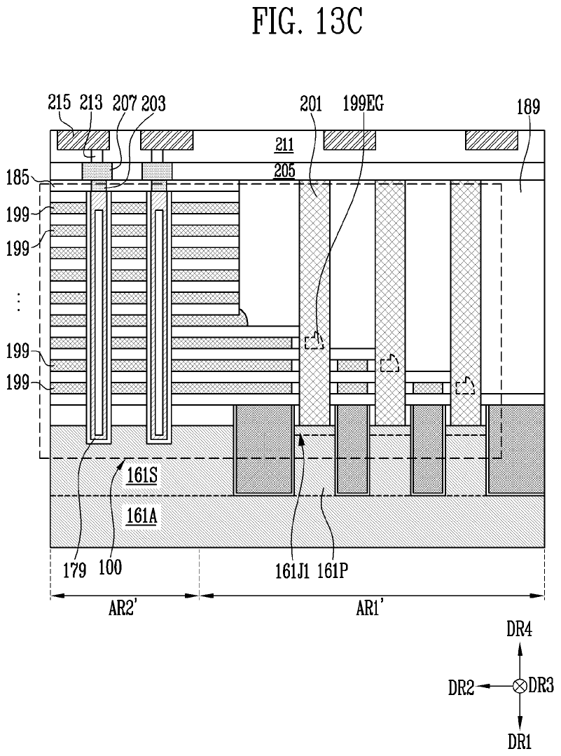

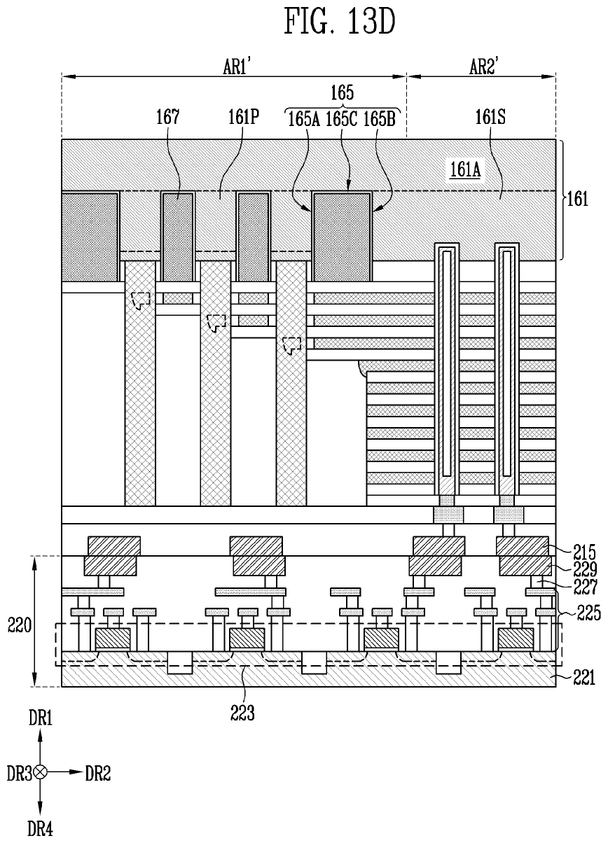

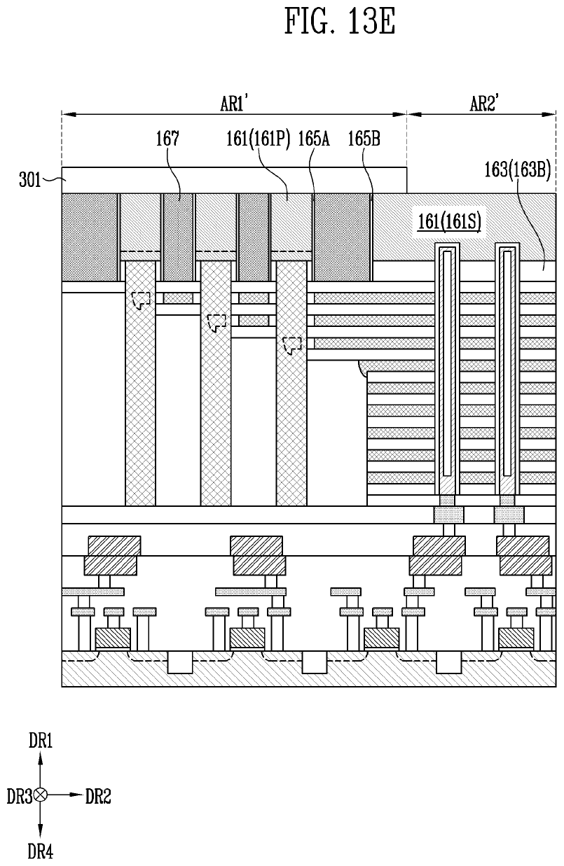

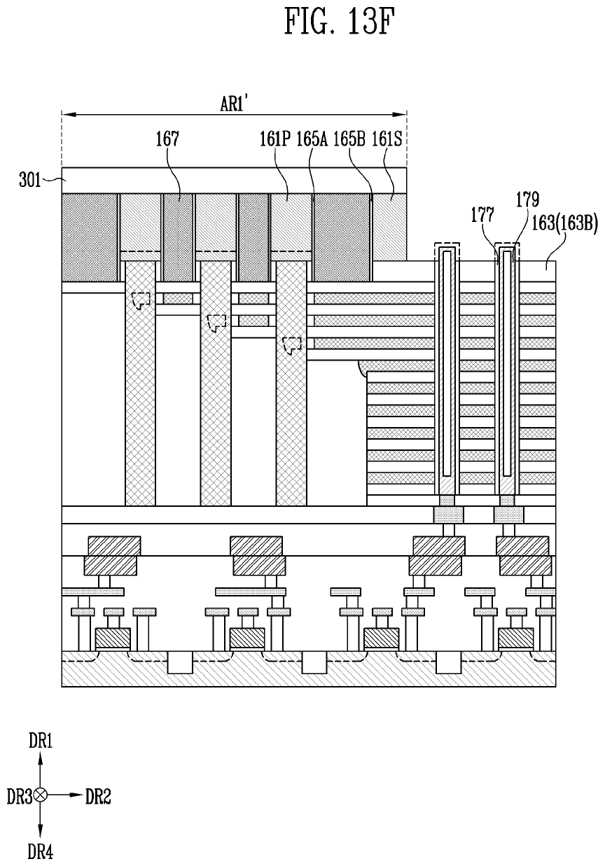

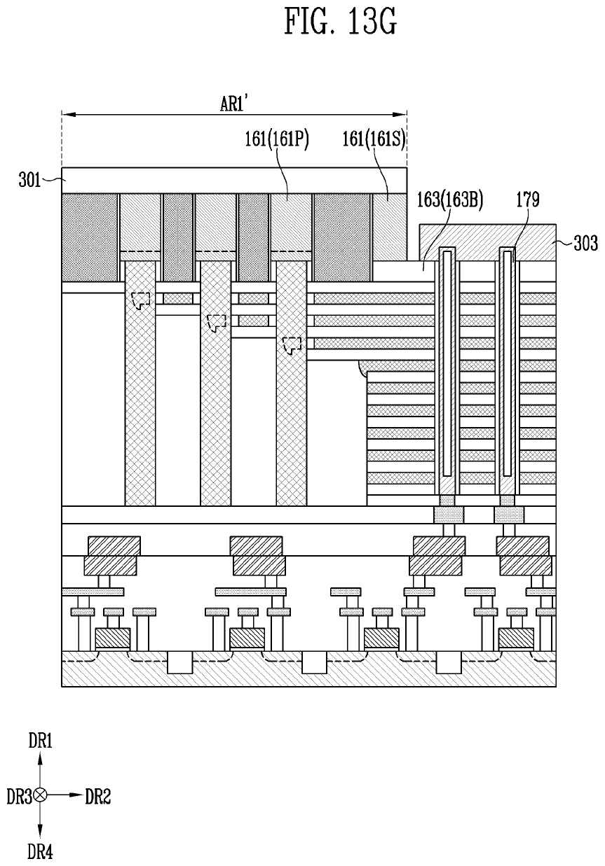

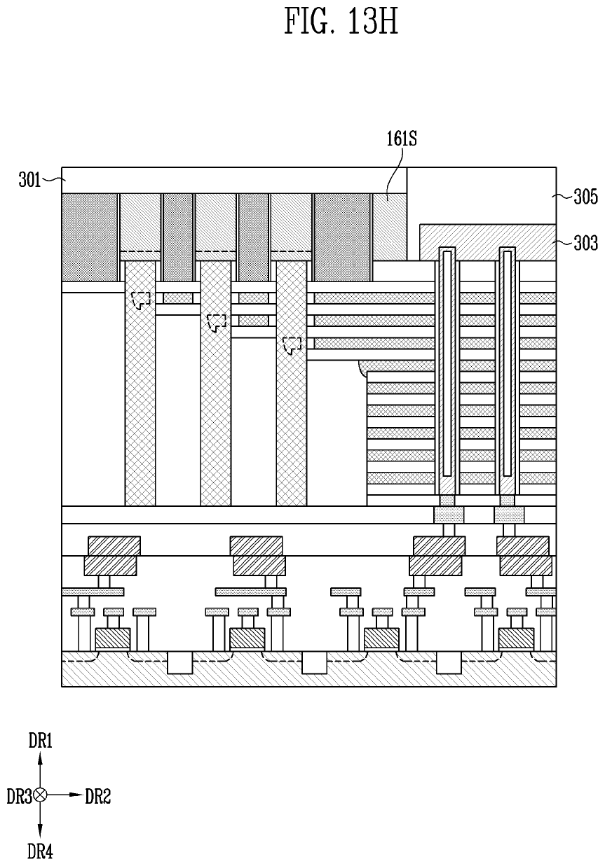

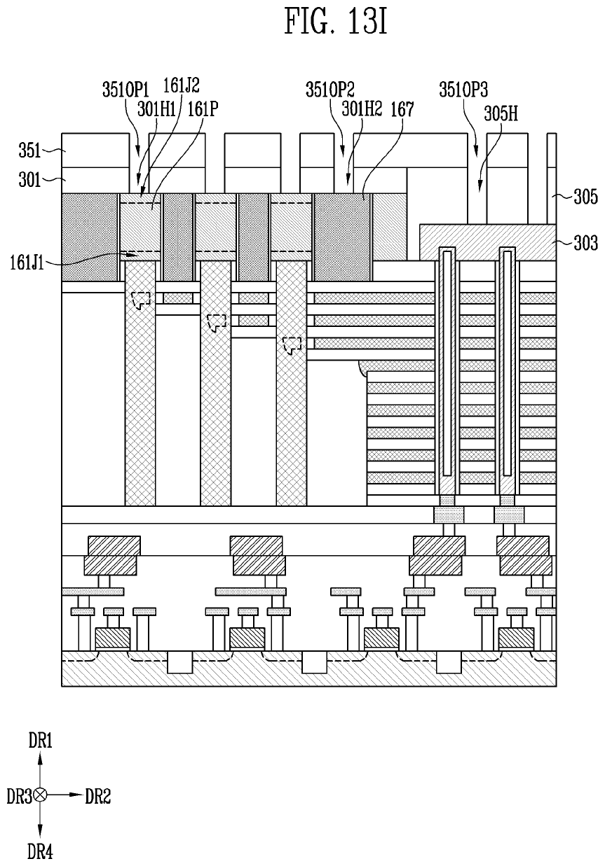

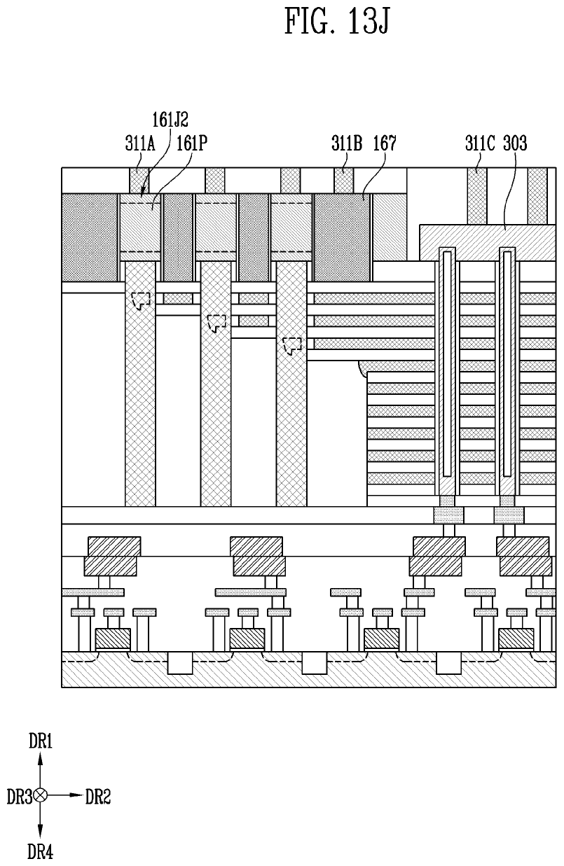

FIGS. 13A to 13J are cross-sectional views illustrating an embodiment of subsequent processes after forming the slit 197 shown in FIG. 12A.

Referring to FIG. 13A, the plurality of second material layers 173 and the plurality of third material layers 187 shown in FIGS. 12A and 12B may be replaced with a plurality of conductive patterns 199 through the slit 197 shown in FIG. 12A. More specifically, the plurality of second material layers 173 and the plurality of third material layers 187 shown in FIGS. 12A and 12B may be selectively removed through the slit 197 shown in FIG. 12A. At this time, even though the fourth material layer 195 is formed of the same material as the third material layer 187 shown in FIG. 12B, the fourth material layer 195 may be protected by the spacer layer 193 and may serve as a support. Subsequently, a conductive material may be formed in a region where the plurality of second material layers 173 and the plurality of third material layers 187 are removed. Thereafter, a portion of the conductive material inside the slit 197 shown in FIG. 12A may be removed so that the conductive material is separated into the plurality of conductive patterns 199. Although not shown in the figure, before forming the conductive material, a metal oxide layer such as an aluminum oxide layer may be formed along a surface of the region where the plurality of second material layers 173 and the plurality of third material layers 187 are removed.

As described above, a gate stack 170G may be defined by replacing the plurality of second material layers 173 and the plurality of third material layers 187 with the plurality of conductive patterns 199. In addition, the memory cell array 100 including the gate stack 170G, the memory layer 177, and the channel pillar 179 may be formed.

The gate stack 170G may include the plurality of first material layers 171 and the plurality of conductive patterns 199. Each of the plurality of first material layers 171 may be used as an interlayer insulating layer. Each of the plurality of first material layers 171 and the plurality of conductive patterns 199 of the gate stack 170G may overlap the second region AR2′ of the semiconductor substrate 161, and may be penetrated by the memory layer 177 and the channel pillar 179. The plurality of conductive patterns 199 of the gate stack 170G may be spaced apart from each other by the plurality of first material layers 171. The plurality of conductive patterns 199 may include a plurality of ends 199EG respectively overlapping the plurality of active pillars 161P. The plurality of ends 199EG of the plurality of conductive patterns 199 may form a stepped structure. Each of the plurality of ends 199EG of the plurality of conductive patterns 199 may be spaced apart from the fourth material layer 195 by the spacer layer 193 corresponding thereto.

Although not shown in the figure, after forming the memory cell array 100, a vertical structure may be formed inside the slit 197 shown in FIG. 12A. The vertical structure may include an insulating material or may include an insulating material and a conductive material.

Referring to FIG. 13B, the plurality of contact holes 191 may be opened by etching the fourth material layer 195 and the spacer layer 193 shown in FIG. 13A. Although not shown in the figure, when a metal oxide layer is additionally formed before forming the plurality of conductive patterns 199, a portion of the metal oxide layer may be exposed by the etching process of the spacer layer 193 shown in FIG. 13A, and the exposed portion of the metal oxide layer may be additionally etched.

According to the above-described process, the plurality of ends 199EG of the plurality of conductive patterns 199 may be exposed by the plurality of contact holes 191. An exposed region of each of the plurality of ends 199EG of the plurality of conductive patterns 199 may form the first sidewall IW1 as described with reference to FIG. 7B.

The etching process of the spacer layer 193 shown in FIG. 13A may be controlled so that a portion of the spacer layer remains as an insulating spacer 193S. The insulating spacer 193S may be disposed inside each of the second recess regions 173R2 shown in FIG. 13A. The etching process of the spacer layer 193 shown in FIG. 13A may be controlled so that the plurality of active pillars 161P are respectively exposed through the plurality of contact holes 191.

Subsequently, a first junction 161J1 may be formed by injecting at least one of an n-type impurity and a p-type impurity into a portion of the plurality of active pillars 161P through the plurality of contact holes 191.

Referring to FIG. 13C, a plurality of gate contact plugs 201 may be formed by filling the plurality of contact holes 191 shown in FIG. 13B with a conductive material. Each gate contact plug 201 may contact an exposed region of the end 199EG of the conductive pattern 199 corresponding thereto. Each gate contact plug 201 may contact the first junction 161J1 of the active pillar 161P corresponding thereto. Accordingly, the plurality of gate contact plugs 201 may connect the plurality of conductive patterns 199 of the memory cell array 100 to the plurality of active pillars 161P.

Thereafter, a bit line contact 203, a bit line 207, a first conductive bonding contact 213, and a first conductive bonding pattern 215 may be formed over the memory cell array 100.

As an embodiment, the bit line contact 203 may be formed in the buffer insulating layer 185. The bit line contact 203 may pass through the buffer insulating layer 185 to contact the channel pillar 179 of the memory cell array 100. Thereafter, an insulating layer 205 may be formed to cover the bit line contact 203, the plurality of gate contact plugs 201, the buffer insulating layer 185, and the filling insulating layer 189. Subsequently, the bit line 207 may be formed in the insulating layer 205. The bit line 207 may pass through the insulating layer 205 to contact the bit line contact 203. Subsequently, a first insulating structure 211 in which the first conductive bonding contact 213 and the first conductive bonding pattern 215 are buried may be formed.

Referring to FIG. 13D, a structure 220 corresponding to the second structure ST2 described with reference to FIG. 3 may be provided. The structure 220 may include a peripheral circuit substrate 221, a peripheral circuit structure 223, a plurality of interconnections 225, a plurality of second conductive bonding contacts 227, and a plurality of second conductive bonding patterns 229 identically to that described with reference to FIG. 3.

Subsequently, a bonding process may be performed so that the plurality of second conductive bonding patterns 229 of the structure 220 are connected to the plurality of first conductive bonding patterns 215.

Referring to FIG. 13E, the first impurity region 161A of the semiconductor substrate 161 shown in FIG. 13D may be removed. At this time, the horizontal portion 165C of the insulating layer 165 shown in FIG. 13D may be removed, and the first vertical portion 165A and the second vertical portion 165B of the insulating layer 165 shown in FIG. 13D may be separated to respectively configure a first pass gate insulating layer and a second pass gate insulating layer. The first impurity region 161A of the semiconductor substrate 161 shown in FIG. 13D may be removed through a selective etching process using a wet etching process or the like.

As the first impurity region 161A of the semiconductor substrate 161 shown in FIG. 13D is removed, the plurality of active pillars 161P and the semiconductor pattern 161S may be separated from each other. A thickness of each of the plurality of active pillars 161P and the pass gate 167 in the first direction DR1 may be controlled by a planarization process such as chemical mechanical polishing (CMP).

Subsequently, a first upper insulating layer 301 may be formed to cover the pass gate 167 and the plurality of active pillars 161P. The first upper insulating layer 301 may be formed to open a portion of the semiconductor pattern 161S remaining in the second region AR2′ of the semiconductor substrate 161. Subsequently, the second region AR2′ of the semiconductor substrate 161 opened by the first upper insulating layer 301 may be removed. Thus, the second interposition portion 163B of the interposition insulating layer 163 may be exposed as shown in FIG. 13F, and a portion of the memory layer 177 may be exposed as indicated by a dotted line of FIG. 13F.

Referring to FIG. 13F, a portion of the memory layer 177 indicated by a dotted line may be removed. Thus, a portion of the channel pillar 179 may be exposed.

Referring to FIG. 13G, a doped semiconductor layer 303 connected to the channel pillar 179 may be formed. The doped semiconductor layer 303 may include at least one of an n-type impurity and a p-type impurity. As an embodiment, the doped semiconductor layer 303 may include an n-type impurity as a majority carrier.

The doped semiconductor layer 303 may be spaced apart from the semiconductor pattern 161S, which remains in the first region AR1′ of the semiconductor substrate 161, in the second direction DR2. The doped semiconductor layer 303 may be formed on the second interposition portion 163B of the interposition insulating layer 163 to cover an exposed region of the channel pillar 179. The doped semiconductor layer 303 may contact the exposed region of the channel pillar 179.

Referring to FIG. 13H, a second upper insulating layer 305 may be formed to cover the doped semiconductor layer 303. The second upper insulating layer 305 may fill a region between the semiconductor pattern 161S and the doped semiconductor layer 303.

Referring to FIG. 13I, a second mask pattern 351 may be formed over the first upper insulating layer 301 and the second upper insulating layer 305. The second mask pattern 351 may include a plurality of openings 351OP1 to 351OP3. The plurality of openings 351OP1 to 3510P3 may include a plurality of first openings 351OP1, a second opening 351OP2, and a third opening 351OP3. The plurality of first openings 351OP1 may overlap the plurality of respective active pillars 161P. The second opening 351OP2 may overlap the pass gate 167. The third opening 3510P3 may overlap the doped semiconductor layer 303.

Subsequently, the first upper insulating layer 301 and the second upper insulating layer 305 may be etched through an etching process using the second mask pattern 351 as an etch barrier. At this time, a portion of each of the first upper insulating layer 301 and the second upper insulating layer 305 exposed through the plurality of openings 351OP1 to 351OP3 may be etched, and thus a plurality of upper holes 301H1, 301H2, and 305H may be formed. The plurality of upper holes 301H1, 301H2, and 305H may include a plurality of first upper holes 301H1, a second upper hole 301H2, and a third upper hole 305H. The plurality of first upper holes 301H1 may pass through the first upper insulating layer 301 to expose each of the plurality of active pillars 161P. The second upper hole 301H2 may pass through the first upper insulating layer 301 to expose the pass gate 167. The third upper hole 305H may pass through the second upper insulating layer 305 to expose the doped semiconductor layer 303.

Subsequently, a second junction 161J2 may be formed by injecting at least one of an n-type impurity and a p-type impurity into a portion of the plurality of active pillars 161P through the plurality of first upper holes 301H1. In each active pillar 161P, a region between the first junction 161J1 and the second junction 161J2 may be used as a channel region.

Thereafter, the second mask pattern 351 may be removed.

Referring to FIG. 13J, a plurality of contacts 311A to 311C may be formed by filling the plurality of upper holes 301H1 to 301H3 with a conductive material. The plurality of contacts 311A to 311C may include a plurality of first contacts 311A, a second contact 311B, and a third contact 311C.

The plurality of first contacts 311A may be respectively disposed inside the plurality of first upper holes 301H1 shown in FIG. 13I. Each first contact 311A may contact the second junction 161J2 of the active pillar 161P corresponding thereto. The second contact 311B may be disposed inside the second upper hole 301H2 shown in FIG. 13I and may contact the pass gate 167. The third contact 311C may be disposed inside the third upper hole 305H shown in FIG. 13I and may contact the doped semiconductor layer 303.

Thereafter, a subsequent process of forming the plurality of upper lines UL1 to UL3 shown in FIG. 3 may be performed.

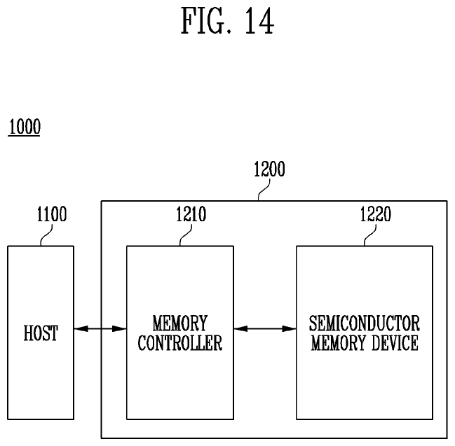

FIG. 14 is a block diagram illustrating an electronic system including a semiconductor memory device according to an embodiment of the present disclosure.

Referring to FIG. 14, the electronic system 1000 may be a computing system, a medical device, a communication device, a wearable device, a memory system, and the like. The electronic system 1000 may include a host 1100 and a storage device 1200.

The host 1100 may store data in the storage device 1200 or read data stored in the storage device 1200 based on an interface. The interface may include at least one of a double data rate (DDR) interface, a universal serial bus (USB) interface, a multimedia card (MMC) interface, an embedded MMC (eMMC) interface, a peripheral component interconnection (PCI) interface, a PCI-express (PCI-E) interface, an advanced technology attachment (ATA) interface, a serial-ATA interface, a parallel-ATA interface, a small computer system interface (SCSI), an enhanced small disk interface (ESDI), integrated drive electronics (IDE) interface, a Firewire interface, a universal flash storage (UFS) interface, and a nonvolatile memory express (NVMe) interface.

The storage device 1200 may include a memory controller 1210 and a semiconductor memory device 1220. As an embodiment, the storage device 1200 may be a storage medium such as a solid state drive (SSD) or a USB memory.

The memory controller 1210 may store data in the semiconductor memory device 1220 or read data stored in the semiconductor memory device 1220 under control of the host 1100.

The semiconductor memory device 1220 may include one memory chip or a plurality of memory chips. The semiconductor memory device 1220 may store data or output stored data under control of the memory controller 1210.

The semiconductor memory device 1220 may be a nonvolatile memory device. As described with reference to FIG. 3, the semiconductor memory device 1220 may include a gate stack disposed between a peripheral circuit structure and a pass gate, and the pass gate may include a plurality of active holes for a plurality of active pillars.

According to various embodiments of the present disclosure, the gate stack may be disposed between the pass gate and the peripheral circuit structure. Thus, in an embodiment, it is possible to improve the integration degree of the semiconductor memory device.

What is claimed is:

1. A semiconductor memory device comprising:
a pass gate;
a plurality of active pillars respectively disposed in a plurality of active holes included in the pass gate; and
a gate stack, the pass gate disposed over the gate stack in a first direction,
wherein the gate stack includes a plurality of conductive patterns spaced apart from each other in the first direction and stacked in the first direction.

2. The semiconductor memory device of claim 1, further comprising:
a first pass gate insulating layer disposed between each of the plurality of active pillars and the pass gate.

3. The semiconductor memory device of claim 1, wherein each of the plurality of active pillars comprises:
a first junction facing the gate stack;
a second junction facing a direction opposite to that of the first junction; and
a channel region between the first junction and the second junction.

4. The semiconductor memory device of claim 1, further comprising:
a plurality of gate contact plugs passing through the gate stack and respectively corresponding to the plurality of active pillars,
wherein each of the plurality of gate contact plugs connects a corresponding active pillar among the plurality of active pillars to a corresponding conductive pattern among the plurality of conductive patterns.

5. The semiconductor memory device of claim 1, further comprising:
a semiconductor pattern surrounding a sidewall of the pass gate at a level where the plurality of active pillars are disposed; and
a second pass gate insulating layer interposed between the semiconductor pattern and the pass gate.

6. The semiconductor memory device of claim 1, wherein the gate stack includes a contact region overlapping the plurality of active pillars and a cell array region extending from the contact region, and
the plurality of conductive patterns are formed in a stepped structure in the contact region of the gate stack.

7. The semiconductor memory device of claim 1, wherein the gate stack includes a plurality of pad portions forming a stepped structure, and
the plurality of pad portions are configured by an end of the plurality of conductive patterns and respectively overlap the plurality of active pillars.

8. The semiconductor memory device of claim 1, further comprising:
a channel pillar disposed in a channel hole of the gate stack; and
a memory layer between the channel pillar and the gate stack,
wherein the gate stack includes a contact region overlapping the plurality of active pillars and a cell array region extending from the contact region in a second direction toward which a side of the plurality of active pillars faces, and
the channel hole passes through the plurality of conductive patterns in the cell array region of the gate stack.

9. The semiconductor memory device of claim 1, further comprising:
a peripheral circuit structure, wherein the pass gate is disposed over the peripheral circuit structure in the first direction, wherein the pass gate is spaced apart from the peripheral circuit structure in the first direction, and wherein the gate stack is disposed between the pass gate and the peripheral circuit structure;
a doped semiconductor layer spaced apart from the pass gate in a second direction toward which a side of the plurality of active pillars faces;
a channel pillar disposed between the peripheral circuit structure and the doped semiconductor layer, extending in the first direction, and connected to the doped semiconductor layer; and
a memory layer surrounding a side of the channel pillar,
wherein the plurality of conductive patterns extend between the doped semiconductor layer and the peripheral circuit structure to surround the memory layer.

10. A semiconductor memory device comprising:
a peripheral circuit structure including a first region and a second region;
a pass gate spaced apart from the peripheral circuit structure in a first direction and overlapping the first region of the peripheral circuit structure;
an active pillar disposed in an active hole of the pass gate;
a doped semiconductor layer spaced apart from the peripheral circuit structure in the first direction and overlapping the second region of the peripheral circuit structure;
a gate stack including a contact region between the first region of the peripheral circuit structure and the pass gate, and a cell array region extending from the contact region to overlap the second region of the peripheral circuit structure;
a channel pillar connected to the doped semiconductor layer and passing through the cell array region of the gate stack;
a memory layer between the channel pillar and the gate stack; and
a gate contact plug connected to the active pillar and passing through the contact region of the gate stack.

11. The semiconductor memory device of claim 10, wherein the gate stack includes a plurality of conductive patterns spaced apart from each other in the first direction and stacked in the first direction, and
the plurality of conductive patterns include a first conductive pattern contacting the gate contact plug and a second conductive pattern insulated from the gate contact plug.

12. The semiconductor memory device of claim 11, further comprising:
a first insulating spacer interposed between the gate contact plug and the first conductive pattern; and
a second insulating spacer interposed between the gate contact plug and the second conductive pattern.

13. The semiconductor memory device of claim 12, wherein the first conductive pattern comprises:
a first inner sidewall contacting the gate contact plug; and
a second inner sidewall extending from the first inner sidewall along a side of the first insulating spacer.

14. The semiconductor memory device of claim 12, wherein the second insulating spacer is formed in an annular shape to surround a side of the gate contact plug.

15. The semiconductor memory device of claim 10, further comprising:
a pass gate insulating layer disposed between the active pillar and the pass gate.

16. The semiconductor memory device of claim 10, wherein the active pillar comprises:
a first junction contacting the gate contact plug;
a second junction facing a direction opposite to that of the first junction; and
a channel region between the first junction and the second junction.

17. The semiconductor memory device of claim 16, further comprising:
a global line connected to the second junction; and
a block select line connected to the pass gate.
